(19) United States
(12) Patent Application Publication
(10) Pub. No.: US 2025/0294703 A1
(43) Pub. Date: Sep. 18, 2025

(54) POOL BOILING SYSTEM AND METHOD OF TRANSFERRING HEAT VIA POOL BOILING

(71) Applicant: The Board of Trustees of the University of Illinois, Urbana, IL (US)

(72) Inventors: Nenad Miljkovic, Urbana, IL (US); Yiyang Chen, Champaign, IL (US); Wuchen Fu, Foster City, CA (US); Mohammad Jalal Inanlu, Urbana, IL (US); Tarandeep Singh Thukral, Urbana, IL (US); Haoyun Qiu, Champaign, IL (US); Bakhshish Preet Singh, Urbana, IL (US)

(21) Appl. No.: 19/077,663

(22) Filed: Mar. 12, 2025

Related U.S. Application Data
(60) Provisional application No. 63/565,635, filed on Mar. 15, 2024.

(51) Int. Cl. H05K 7/20

(52) U.S. Cl. CPC H05K 7/20236

(57) ABSTRACT

A system for transferring heat via pool boiling comprises a pool containing a liquid refrigerant and a component which is partially or fully submerged in the pool. The component has a microstructured surface including cavities having a linear size of at least 5 μm, and the microstructured surface is in contact with the liquid refrigerant. The system exhibits a pool boiling heat transfer coefficient (HTC) of at least 8 kW/m²K for a heat flux in a range from 15-85 kW/m². In some examples, a refrigerant boiling HTC enhancement ratio of up to 2.5 or higher may be achieved using the component with the microstructured surface, in comparison with a plain (unetched) component.

### RELATED APPLICATION

The present patent document claims the benefit of priority under 35 U.S.C. 119(e) to U.S. Provisional Patent Application No. 63/565,635, which was filed on Mar. 15, 2024, and is hereby incorporated by reference in its entirety.

### TECHNICAL FIELD

The present disclosure relates generally to heat transfer systems and methods, and more particularly to a pool boiling system and method.

### BACKGROUND

Pool boiling is a primary heat transfer mode widely used in flooded evaporators in water or air-cooled chillers which service refrigeration and air-conditioning applications. This process is ubiquitous to large scale residential and commercial building chillers which are used to cool the air in the occupant space by distributing the cooled water to fan coils around the structure. Due to the energy demand for residential and commercial building air conditioning, which can reach to 49% of overall building energy utilization over the summer months, understanding the refrigerant boiling process and making it more efficient is key to creating more compact chillers and more environmentally friendly cooling solutions. In addition to stationary applications such as buildings, large high-capacity chillers are also key to mobile platforms such as naval vessels where they provide air conditioning to both crewed and un-crewed (machinery) cabins and cooling for a number of sensitive heat dissipating components such as the drive train, high power electronics, auxiliary systems, and power delivery infrastructure. In addition to environmental conditioning, the rising cooling demands of high heat flux electronics for compute and sensing applications has drawn attention to studies of fluorine-based refrigerants and dielectric fluid pool boiling. By immersing the electronics components in a flowing or quiescent bath of low-saturation temperature fluid such as fluorinated refrigerants, heat can be absorbed by the pool boiling process from the chips, thereby efficiently cooling the component and taking advantage of the high latent heat

### BRIEF DESCRIPTION OF THE DRAWINGS

FIGS. 1A and 1B are schematics illustrating a pool boiling system and method including a component comprising a heat exchanger tube (in FIG. 1A) and a component comprising an electronic device (in FIG. 1B).

FIGS. 2A and 2B show top view and side view schematics of a refrigerant pool boiling test facility comprising an environment chamber and a water loop used for heating.

FIGS. 3A-3D show schematics of fabrication procedures used to create external micro/nanostructured surfaces on copper and aluminum tubes including etched aluminum, boehmite and copper oxidation surfaces; inset images show top-view scanning electron microscope (SEM) images of the plain (unprocessed) and structured surfaces after processing.

FIGS. 4A-4F show confocal imaging characterization of plain aluminum, boehmite (AlO(OH)), etched aluminum surface in large scale (˜700 μm); plain copper, copper oxidation (CuO), and etched aluminum surface in small scale (˜100 μm), respectively.

FIGS. 5A-5F show refrigerant boiling heat transfer coefficient (hₒ, or HTC) on plain copper and CuO structured tubes as a function of boiling heat flux (q″) at two different saturation temperatures and for refrigerants R-134a, R-1336mzz(E) and R-1336mzz(Z); uncertainty bars in heat flux are lower than ±30% and are not shown for clarity, and the sample legend in FIG. 5A is valid for FIGS. 5B-5F.

FIGS. 6A-6F show refrigerant boiling heat flux (q″) on plain copper and CuO structured copper tubes as a function of average wall superheat (ΔT) at two different saturation temperatures and for refrigerants R-134a, R-1336mzz(E) and R-1336mzz(Z); the sample legend in FIG. 6A is valid for FIGS. 6B-6F.

FIGS. 7A-7F show refrigerant boiling heat transfer coefficient (hₒ) on plain aluminum tubes, etched aluminum tubes, and boehmite structured tubes as a function of applied heat flux at two different saturation temperatures and for refrigerants R-134a, R-1336mzz(E) and R-1336mzz(Z); uncertainty bars in heat flux are not shown for clarity.

FIGS. 7G-7I show confocal images at the same magnification (˜700 μm) for plain aluminum, boehmite, and etched aluminum surface.

FIGS. 8A-8F show refrigerant boiling HTC enhancement ratio (φ) as a function of heat flux (φ vs. q″) with different refrigerants for the etched aluminum, CuO and boehmite structured tubes.

FIGS. 9A-9C show refrigerant boiling HTC enhancement ratio (φ) as a function of heat flux (φ vs. q″) on the etched aluminum, CuO and boehmite structured tubes for different refrigerants.

FIG. 10 shows experimentally measured bubble departure diameter (D_{departure}) as a function of the theoretical bubble departure characteristic length scale (D_{b}), where the experimental data were obtained at a heat flux of q″=25 kW/m² using a high-speed camera.

FIG. 11 shows heat transfer coefficient enhancement ratio as a function of normalized structure size (Rₙ) using preliminary data; additional data are plotted in FIG. 17.

FIGS. 12A-12D show, respectively, pre-treatment of Cu tubes, with confocal and SEM characterization of the plain tube shown in the inset images; etching method for a copper tube utilizing H₂O₂ (“Recipe I”) and its SEM characterization depicted in the inset; etching method a copper tube utilizing FeCl₃ (“Recipe II”) and its SEM characterization depicted in the inset; post-treatment cleaning methods used for the etched tube samples (Recipe I and II).

FIGS. 13A-13D show confocal imaging characterization of the exterior structure of etched Cu tubes, including, respectively: low magnification characterization of the H₂O₂ etched surface; higher magnification characterization of the H₂O₂ etched surface; low magnification characterization of the FeCl₃ etched surface; and higher magnification characterization of the FeCl₃ etched surface.

FIGS. 14A and 14B show height profiles from confocal imaging characterization of the H₂O₂ etched Cu tube and FeCl₃ etched Cu tube, respectively, where the line scans are obtained along the labeled lines of the confocal images separating the shaded and unshaded potions.

FIGS. 15A-15C show boiling heat transfer coefficient (hₒ) as a function of heat flux (hₒ vs. q″) for the FeCl₃ etched Cu tube, the H₂O₂ etched Cu tube, and the plain Cu tube with refrigerants R-134a, R-1336mzz(E) and R-1336mzz(Z), respectively.

FIGS. 16A-16C show enhancement ratio as a function of boiling heat flux (φ vs. q″) for the FeCl₃ etched Cu tube and the H₂O₂ etched Cu tube in R-134a, R-1336mzz(E) and R-11336mzz(Z), respectively.

FIG. 17 shows refrigerant boiling HTC enhancement ratio (φ) for boiling heat transfer coefficient (hₒ) as a function of normalized structure size (Rₙ) for R-134a, R1336mzz(E), and R-1336mzz(Z).

FIGS. 18A-18C show boiling heat flux as a function of average wall superheat (q″ vs. ×T) for the FeCl₃ etched Cu tube, the H₂O₂ etched Cu tube, and the plain Cu tube in R-134a, R-1336mzz(E) and R-1336mzz(Z), respectively.

### DETAILED DESCRIPTION

Described in this disclosure is a pool boiling system and method that utilize a controlled surface structure on a heat exchanger tube or other component to provide effective cooling, with common third-generation refrigerants and potential next-generation low global warming potential (low-GWP) refrigerants.

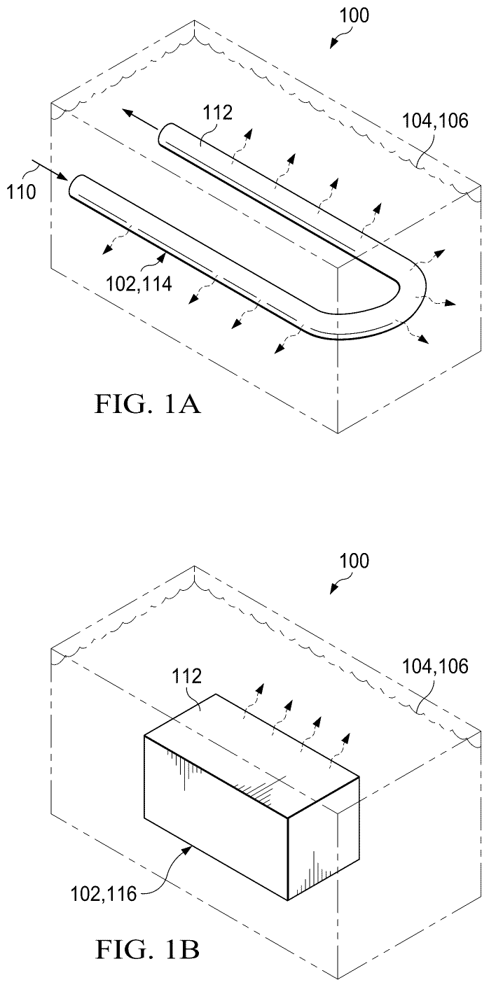

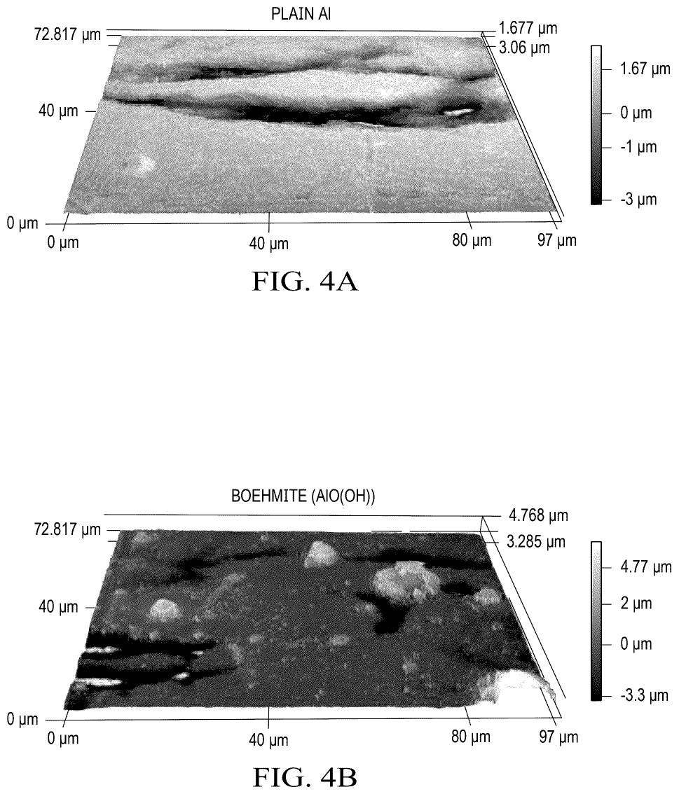

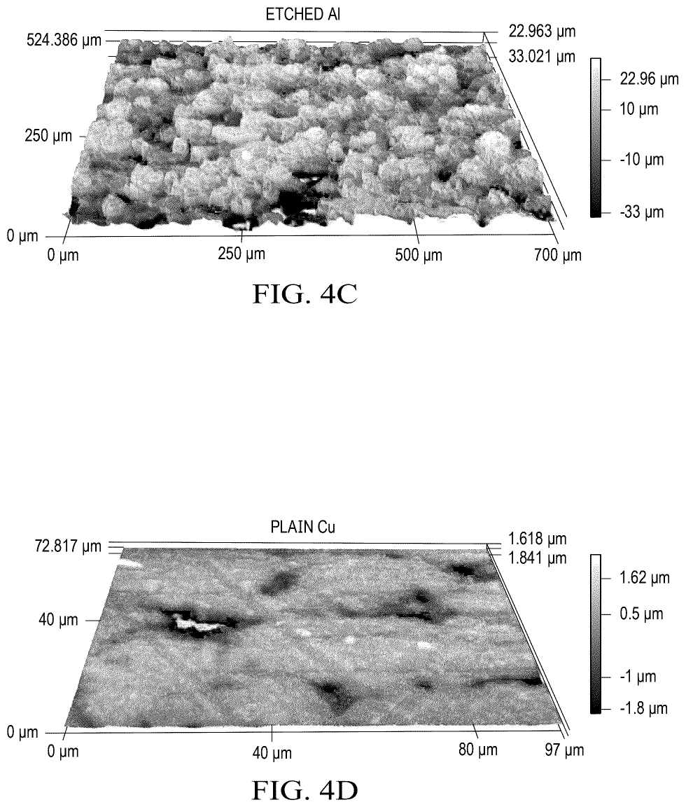

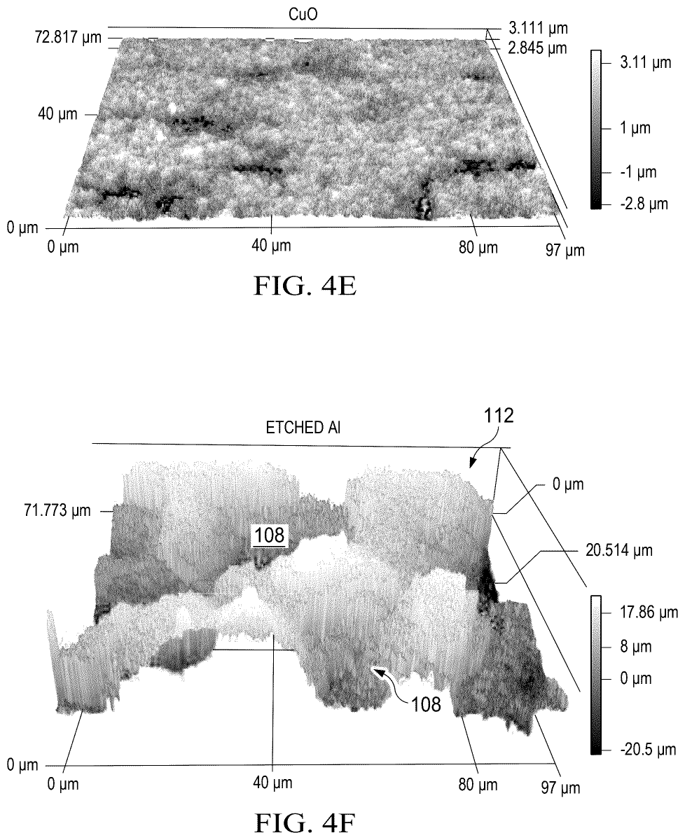

Referring to FIGS. 1A and 1B, the pool boiling system 100, which may be referred to as a flooded shell and tube evaporator, includes a component 102 partly or completely submerged in a pool 104 comprising a liquid refrigerant 106. The component 102 has a microstructured surface 112 with cavities 108 of a controlled size (see also FIG. 4F). More specifically, the cavities 108 may have a peak to valley depth (or “linear size”) of at least 5 microns and as high as 100 microns; in this size range, when the microstructured surface 112 is in direct contact with the liquid refrigerant 106 and heat is transferred from the component 102 to the liquid refrigerant 106 in the refrigerant pool 104, the microstructured surface 112 may promote highly efficient pool boiling. For example, a boiling heat transfer coefficient (hₒ) of at least about 8 kW/m²K for a heat flux in a range from 15-85 kW/m² may be achieved during nucleate boiling. Boiling of the refrigerant 106 is indicated by the curved arrows in FIGS. 1A and 1B. The microstructured surface 112 may form part or all of the external surfaces of the component 102.

The heat to be removed may be generated by the component 102 itself (e.g., in the case of an electronic device 116) or may be provided by a heat transfer fluid 110 being flowed through the component 102 (e.g., in the case of a heat exchanger tube 114, or a heat spreader). For example, referring to FIG. 1A, a tube 114 or a bundle of tubes may be immersed in a quiescent pool 104 of liquid refrigerant 106, with the heat transfer fluid (a coolant such as water) 110 flowing through the tube 114 and rejecting heat to the refrigerant pool 104, 106, resulting in pool boiling on the microstructured external surface 112 of the tube 114. The term “quiescent” means the pool 104 of liquid refrigerant 106 is a stagnant, non-flowing volume of liquid refrigerant 106. In another example, as illustrated in FIG. 1B, the component 102 may comprise an electronic device 116 or a heat spreader in contact with the electronic device 116, and the microstructured surface 112 may form part or all of an external surface of the heat spreader and/or the electronic device 116. As in the previous example, the component 102, 116 may be immersed in a quiescent pool 104 of liquid refrigerant 106. The electronic device 116 may comprise a chip package, multi-chip module, battery pack, or server, for example.

In some examples, the HTC achieved by the pool boiling system may be at least 12 kW/m²K, at least 20 kW/m²K, or at least 30 kW/m²K, and/or as high as 50 kW/m²K for a heat flux in the range from 15-85 kW/m². These HTC values are supported by experimental data described below. The liquid refrigerant within the pool may comprise a hydrochlorofluorocarbon (HCFC), a hydrofluoro-olefin (HFO), a hydrofluorocarbon (HFC), such as 1,1,1,2-tetrafluoroethane (R134a), and/or another environmentally friendly fluid. The refrigerant may have a low GWP, such as a GWP less than 1500, and in some examples the GWP may be less than 20, and as low as 0. For example, the liquid refrigerant may comprise R134a (GWP of about 1430), R1336mzz(E) (GWP of about 7-18), and/or R1336mzz(Z) (GWP of about 2). A zeotropic or azeotropic blend may be used. Other suitable refrigerants may include dielectric fluids configured for direct contact with electronic devices, such as fluorinated ketones, which may be available commercially under the tradenames Novec™ and Fluorinert™ (e.g., Fluorinert Electronic Liquid FC-72).

The term “microstructured surface” may be understood to refer to a surface including microscale roughness features, which may be produced by chemical processing (e.g., wet etching) of a component. Accordingly, the term “etched surface” may be used instead of “microstructured surface” or “structured surface” at some places in this disclosure. The component that undergoes chemical processing may comprise a thermally conductive metal such as aluminum or copper. In some examples, the surface of the component is intentionally immersed in an acidic solution for wet etching, where the corrosive solution removes a small amount of material from the surface, resulting in a microstructured surface with specific textures and roughness (e.g., etched Al and etched Cu). In other examples, the surface undergoes oxidation by being immersed in an oxidizing agent (e.g., forming CuO or boehmite). The microscale roughness features may take the form of protrusions or peaks between which cavities, pores, or valleys (collectively referred to as “cavities” or “microcavities” 108) may be defined, as shown in the confocal image of FIG. 4F, which is discussed further below. The microcavities may serve as nucleation sites for pool boiling. A large number of cavities in the desired size range yields a higher density of nucleation sites and improved heat transfer coefficients. It has been found in experiments described below that if the cavities of the microstructured surface are sub-microscale in size, e.g., less than 5μm, or less than 10 μm in linear size, such as from 10 nm to 1 micron in linear size, then they may be too small to be activated for pool boiling. In contrast, cavities of at least 5 μm in linear size, and preferably at least 10 μm or at least 20 μm in linear size, and up to 50 μm in linear size, or up to 100 μm in linear size, may be activatable for pool boiling. Accordingly, it is preferred that at least 70%, at least 80%, at least 90%, and/or up to 100% all of the cavities of the microstructured surface are at least 5 μm, or preferably at least 10 μm or at least 20 μm in linear size, and as high 50 μm or as high as 100 μm in linear size. Beyond this size range, the component (e.g., heat exchanger tube(s) or heat spreader) may incorporate fins or other surface area-increasing macroscale features. Fin structures are typically 250 μm or higher in size. In some examples, such fins or other large macroscale features may be further etched to include the microstructured surface described in this disclosure.

In addition to a pool boiling system, a method of transferring heat utilizing pool boiling is explained, also in reference to FIGS. 1A and 1B. The method entails partially or fully submerging a component 102 in a pool 104 comprising a liquid refrigerant 106, where the component 102 has a microstructured surface 112 including cavities having a linear size as described above. The microstructured surface 112 is typically an external surface of the component 102 and is in direct contact with the liquid refrigerant 106. The component 102 may be a heat exchanger tube 114 or a bundle of tubes configured for flow of water or another coolant fluid 110 therethrough. Alternatively, the component 102 may comprise an electronic device 116 or a heat spreader in contact with the electronic device 116. As indicated above, the heat to be removed may be generated by the component 102 itself (e.g., in the case of the electronic device 116) or may be provided by a heat transfer fluid 110 being flowed through the component 102 (e.g., in the case of the heat exchanger tube 114 or a heat spreader). In either case, heat transfer to the liquid refrigerant 106 occurs via pool boiling at the microstructured surface with a boiling heat transfer coefficient (hₒ, or HTC of at least about 8 kW/m²K for a heat flux in a range from 15-85 kW/m². In some examples, the HTC may be at least 12 kW/m²K, at least 20 kW/m²K, or at least 30 kW/m²K, and/or as high as 50 kW/m²K at the heat flux in the range from 15-85 kW/m². The liquid refrigerant 106 employed for pool boiling may have any of the characteristics or properties described above or elsewhere in this disclosure. The pool boiling process may take place under ambient conditions (e.g., at room temperature (˜18-23° C.) and/or atmospheric pressure).

Preferably, a refrigerant boiling HTC enhancement ratio of at least 1.5 is achieved, where the enhancement ratio φ is defined as a ratio of the HTC (h_{o,structured}) for an structured component (that is, a component having a microstructured or nanostructured surface) to the HTC for a plain (unetched) component

$$( {h}_{o , p l a i n} ) : φ = \frac{{h}_{o , structured}}{{h}_{o , plain}} .$$

In some examples, the enhancement ratio φ may be up to or at least 2, or up to or at least 2.5, as shown in the examples below for etched aluminum and copper tubes with microscale cavities. To account for the effects of refrigerant properties, a normalized structure size is defined as:

$${R}_{n} = \frac{{R}_{s t r u c t u r e}}{{R}_{nucleation}} .$$

As explained in the Examples below. Here, R_{structure} represents the cavity size observed from scanning electron microscopy (SEM) and confocal analysis, R_{structure} has similar definition with peak to peak roughness Rₚ, and the critical nucleation radius R_{nucleation} is the critical bubble embryo size which can be obtained by combining the Clausius-Clapeyron equation with the Young-Laplace equation. Preferably, the normalized structure size Rₙ is greater than 4.

As indicated above, the component may undergo etching and/or oxidation to form the microstructured surface configured to promote pool boiling. Etching and oxidation chemistries suitable for aluminum and copper components (e.g., tubes, heat spreaders) have been developed. The resulting processed surfaces may exhibit cavity sizes ranging from the nanoscale to the microscale, depending on the component material and etch chemistry. Tubes having oxidized surfaces including boehmite (AlO(OH)) nanostructures, copper oxide (CuO) microstructures and etched surfaces including etched aluminum are shown in the examples below to enhance or inhibit the boiling HTC of three different refrigerants. The etched surfaces include cavities having characteristic length scales of 100 nm, 1 μm, and 10 μm for boehmite, CuO, and etched aluminum, respectively. The pool boiling experiments described below show that aluminum tubes having microstructured surfaces including nominally 10 μm cavities may yield up to a 250% increase in boiling HTC compared to smooth (unetched) aluminum tubes, depending on the refrigerant employed. Utilizing R-1336mzz(E), the boiling HTC may be increased by up to 175%; utilizing R-1336mzz(Z), the boiling HTC may be increased by up to 150%; and utilizing R-134a, the boiling HTC shows the greatest increase of up to 250%. Copper tubes processed to include copper oxide structures are shown to exhibit a 25% enhancement in HTC compared to smooth copper tubes utilizing R-134a and R-1336mzz(E) at higher heat fluxes but show minimal improvements at lower heat fluxes. The etched copper tubes show no enhancement within the range of tested heat flux utilizing R-1336mzz(Z). Aluminum tubes processed to include boehmite structures are shown to result in a 5-15% decrease in boiling HTC for all three refrigerants and at all tested heat fluxes. This is believed to be due to the non-optimal size of the surface cavities produced by chemical processing.

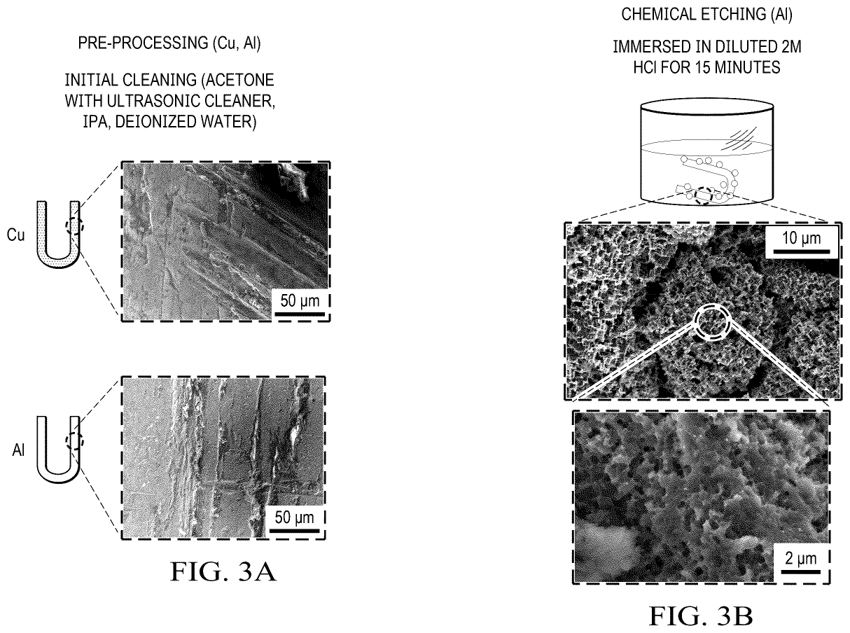

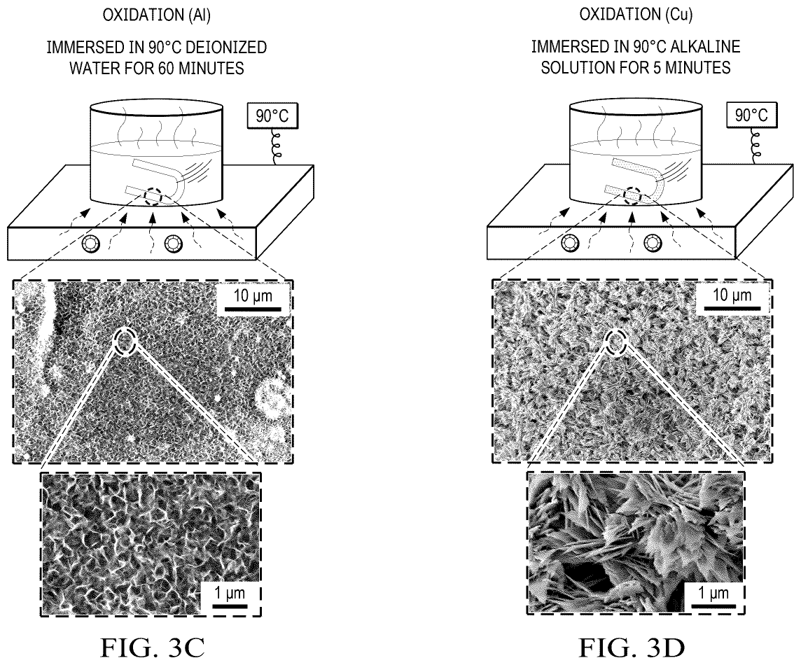

Due to the exceptional heat transfer performance achieved by the etched aluminum tube including microscale cavities, the etching method developed for aluminum tubes or other aluminum components is described here. Also, a new method to prepare etched copper tubes with microscale cavities is also described. Referring to FIG. 3A, the method for preparing an etched aluminum tube may include a first step of cleaning the surface to be etched, typically an external surface of the component, with an organic solvent and/or deionized water. The organic solvent may include acetone and/or isopropanol. The cleaning may comprise immersing the component in the organic solvent and/or the deionized water (e.g., in an ultrasonic cleaner) or otherwise exposing the external surface to the organic solvent and/or the deionized water. In one example, the cleaning comprises immersing the component in acetone, isopropanol, and the deionized water in succession. After cleaning, the external surface is exposed to a hydrochloric acid (HCl) solution comprising a HCl concentration of 2 M to 5 M, as illustrated in FIG. 3B. Typically, the exposure entails immersing the component into the HCl solution, and the exposure may occur for a time duration from about 7 min to about 30 min, or from about 15 min to about 25 min. An internal surface of the component may be protected or covered during the exposure to the HCl solution such that only the external surface is etched. After the exposure, the external surface may be rinsed with deionized water and then dried (e.g., in nitrogen), thereby obtaining the microstructured surface with surface cavities of a controlled size. Typically, the method is carried out at room temperature (e.g., 18° C.-25° C.). The etching methods illustrated in FIGS. 3C and 3D are discussed below.

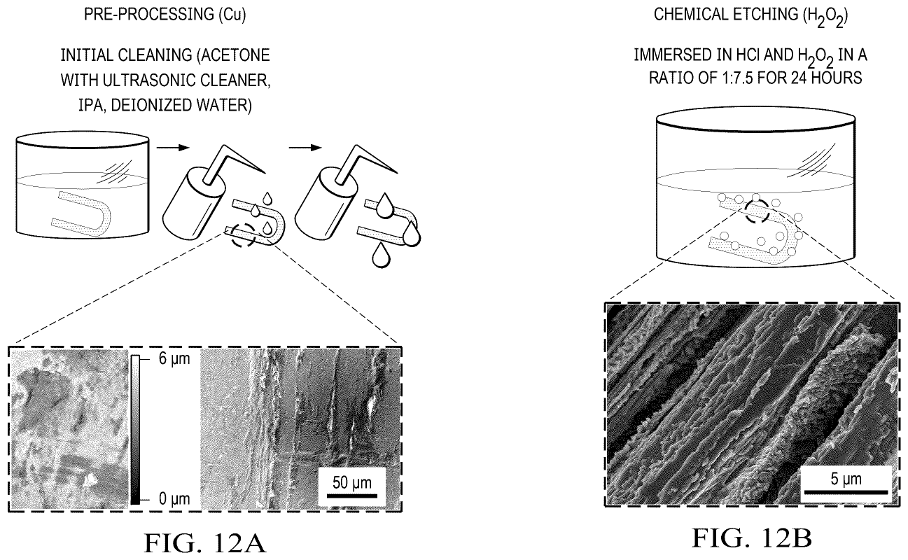

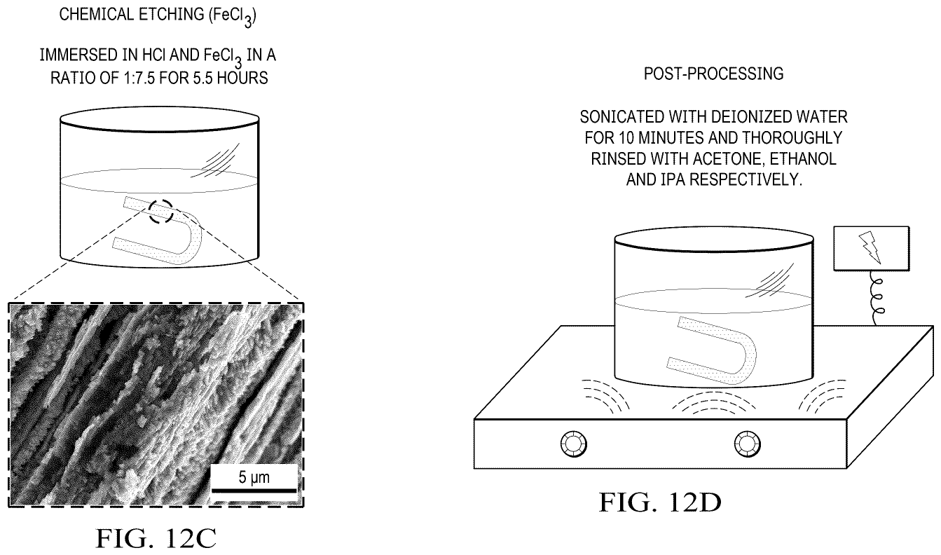

The new etching method for preparing copper tubes with microscale roughness features or cavities is described in detail in the Examples below in reference to FIGS. 12A-12D. The method is summarized here. The method includes exposing a component comprising copper, such as a copper tube, to an etchant solution that includes ferric chloride (FeCl₃) or hydrogen peroxide (H₂O₂) as an oxidant, and hydrochloric acid. The oxidant and the hydrochloric acid have a volume ratio (oxidant:acid) in a range from 1:6 to 1:8 in the etchant solution, and more preferably from 1:7 to 1:8. The etching may take place for a time duration from 2 hours to 30 hours. If the oxidant is ferric chloride, then the time duration is typically from 2 hours to 8 hours, and if the oxidant is hydrogen peroxide, and the time duration is typically from 20 hours to 30 hours.

### EXAMPLES

### Experimental Setup for Pool Boiling Tests

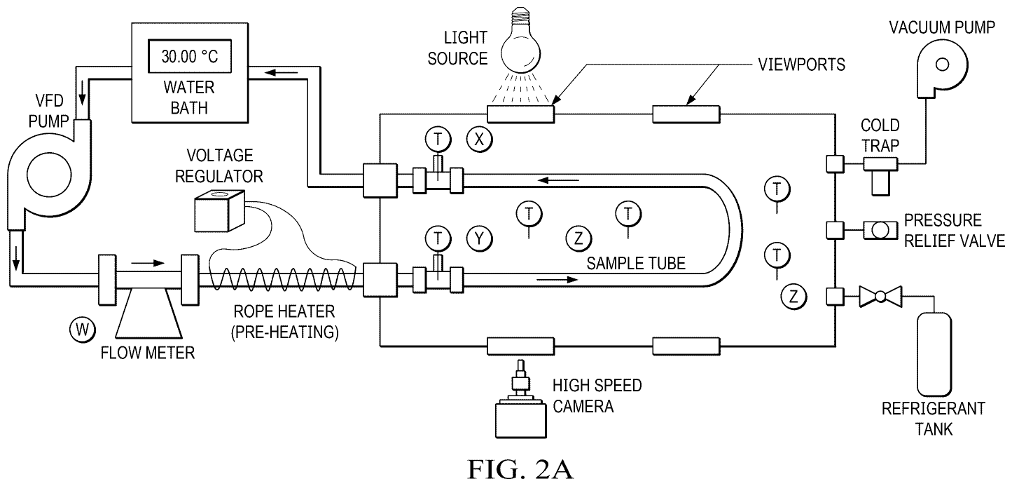

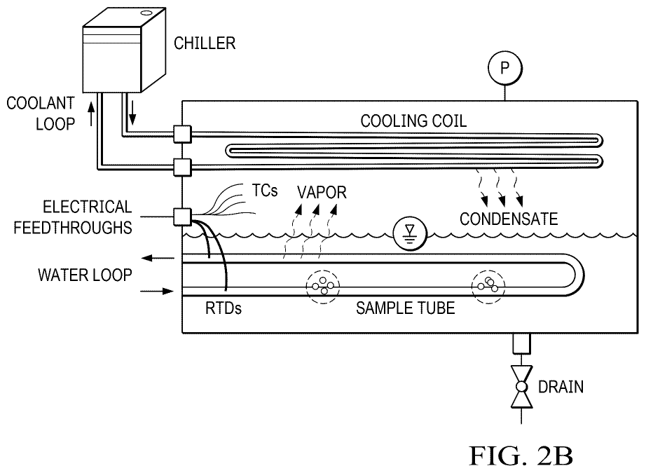

FIGS. 2A and 2B illustrate a top-view schematic of the test facility and a side-view schematic of the environment chamber. The system includes two flow loops and an environment chamber. The two flow circuits are a hot water loop and a coolant loop, where the hot water loop serves as the heat source for boiling, and the coolant loop is used for adjusting the steady state conditions inside the chamber. Within the hot water loop, a U-shaped sample tube is placed inside the chamber and submerged in a pool of liquid refrigerant. A water bath (PolyScience, AD45R-20), variable frequency drive (VFD, ABB, ACS150) pump (Micropump, GC-M35), Coriolis flow meter (Emerson, CMF series), and rope heater are used to control and measure the hot water temperature and flow rate. The water bath provides precise adjustment of the bulk water reservoir temperature, having a resolution of ±0.1° C. A rope heater is connected to a voltage regulator and applied to a pre-heating section (20 cm) before the water enters the environment chamber. The pre-heating section has two functions. One is to supplement the total heating power so that the heating capacity of the system is increased, and the second purpose is to avoid entrance effects where the water is not hydrodynamically fully developed. For turbulent flow, the hydrodynamic entry length (L_{hd}) can be estimated as:

$${L}_{h d} \approx 10 {D}_{i} , \qquad ( 1 )$$

where Dᵢ is the hydraulic diameter. For the test sections, the entrance length is estimated to be L_{hd}<5 cm and is shorter than the pre-heating section (20 cm).

The VFD pump is added in series with the water bath to increase the total water head and enable higher flow rates. The Reynolds number of the hot water loop (as measured at the sample to be Re_{ID}=4\dot{m}_{water}/(πμDᵢ), where \dot{m}_{water} is the mass flow rate of water, μ is the dynamic viscosity of water obtained at the average temperature of inlet and outlet, and Dᵢ is 4.72 mm and 4.57 mm for the copper and aluminum tubes, respectively) is kept between 12,000 to 38,000, enabling turbulent internal convective heat transfer. The water inlet and outlet temperatures are measured by 2 resistance temperature detectors (RTDs, Reotemp, Class AA). An RTD with Fluke 1502A thermometer readout is used for calibration. RTD readings and thermocouple readings ranging from 5 to 60° C. are recorded with an increment of 5° C. A linear fit is applied on RTD readings as a function of the thermocouple (TC) readings and is used in a Lab View program for calibration. All RTDs and thermocouples are fed into the chamber by electrical feedthroughs (Conax, TG-24, and PL-18). A pressure sensor (MKS, Baratron 750C) is used to measure the saturation pressure inside the chamber with an ±5 kPa uncertainty. Acknowledging the possibility of temperature variation along the bulk refrigerant height, the sample tubes are positioned 5 cm below the surface layer of the refrigerant to ensure free volume pool boiling. Additionally, four independent thermocouples are strategically placed at the same height as the sample tube to monitor the bulk refrigerant temperature. All the thermocouples are calibrated prior to use. Calibration was done with a refrigerated circulation bath (PolyScience, AP-15R) filled with water ethylene glycol mixture (50%-50% weight %). A ±0.25° C. uncertainty in bulk refrigerant temperature measurement is used for uncertainty analysis herein.

A coolant loop is installed at the top hemisphere inside the cylindrical chamber to facilitate condensation of the boiled off refrigerant from the sample. The coolant loop includes a chiller (PolyScience, 6500 Series) and a copper cooling coil. The chiller can control the inlet temperature of the coolant (water/ethylene glycol, 50:50 weight % mixture) to maintain the saturation temperature inside the chamber. Once a steady state is reached, data recording starts for 2 minutes (National Instrument & LabView). On the rear side of the chamber, a vacuum line is assembled for vacuuming the system below 67 Pa before charging the refrigerant. A pressurized nitrogen tank (Airgas, 2500 psi) is connected to the chamber to check for leakage before running any experiments. For safety purposes, a pressure relief valve (SS-4R3A, Swagelok) is installed and connected to the outside of the building. The relief valve automatically opens when chamber pressure exceeds 1,500 psi (10.3 MPa).

On the bottom hemisphere of the chamber, there is a drainage port for recovering the refrigerant. On top of the chamber, a pressure transducer (MKS, Baratron 750C) is used to measure the vapor pressure during experiments. The test chamber has three viewports (PresSure Products Company, 2″ Bull's Eye) on each side and a high-speed camera (Photron, FASTCAM Mini AX200) recording videos at 5,000 frames per second (FPS).

The pool boiling working conditions are chosen to mimic a typical operating range for refrigerant evaporators with a heat flux range of 20-90 kW/m². Refrigerants R134a, R-1336mzz(E), or R-1336mzz(Z) are used as the boiling working fluid (refrigerant). Two saturation temperatures of 20° C. and 30° C. are chosen to ensure the results are repeatable at different reduced pressure (Pr). The selection of these two saturation temperatures, 20° C. and 30° C., was motivated by the cooling capacity of the chiller. These temperatures are not aligned with typical chiller applications, which typically reach below 5° C. However, the fundamental mechanism of enhancing pool boiling remains consistent irrespective of different saturation temperatures used within this study due to the small difference (5° C. vs. 30° C.). Reduced pressure is a key parameter in many pool boiling correlations accounting for the effect of different refrigerant properties and working conditions. All experiments start from high heat flux (>90 kW/m²) to lower heat flux, in order to eliminate any potential hysteresis influence. Table 1 presents key thermophysical properties of the refrigerants tested at the two saturation temperatures.

TABLE 1
Key properties of the refrigerants studied at saturation
temperatures of 20° C. and 30° C.

| | | | | | | |
|---|---|---|---|---|---|---|
| | σ | ρ₁ | ρᵥ | hₗᵥ | P_{corr} | Pᵣ |
| Refrigerant | [mN/m] | [kg/m³] | [kg/m³] | [kJ/kg] | [kPa] | [—] |

Tₛₐₜ = 20° C.

| | | | | | | |
|---|---|---|---|---|---|---|
| R-134a | 8.92 | 1224 | 27.8 | 182.3 | 571.7 | 0.1409 |
| R-1336mzz(E) | 10.35 | 1333.3 | 12.2 | 146 | 164.4 | 0.05943 |
| R-1336mzz(Z) | 14.3 | 1383.5 | 4.2 | 171 | 60.3 | 0.02071 |

Tₛₐₜ = 30° C.

| | | | | | | |
|---|---|---|---|---|---|---|
| R-134a | 7.58 | 1187 | 37.56 | 173.1 | 770.1 | 0.1899 |
| R-1336mzz(E) | 9.18 | 1204.8 | 16.7 | 140 | 229.6 | 0.07308 |
| R-1336mzz(Z) | 13.1 | 1351.4 | 6.05 | 167.9 | 89.4 | 0.03069 |

### Preparation and Characterization of Etched Surfaces (Example 1)

The tubes used in the experiments were commercial 0.25″ copper (McMaster, 8967K88, 122 grade) and 0.25″ aluminum tubes (McMaster, 89965K431, 6061 grade). Deoxidized with phosphorus, 122 copper has good properties compatible with heavy forming processes such as tube manufacture. Mechanically, 122 copper is almost identical to 110, and has good corrosion resistance in aqueous environments. The major advantage of 122 over 110 is that it is easier to form and has superior weldability and brazing capability. It can be easily hot and cold formed. This copper grade is typically used in pipes and tubing. Details of the copper and aluminum tube dimensions can be found in Table 2. Two structures were applied to the outer surface of the aluminum tubes, namely boehmite and etched aluminum, while one structure was applied to the copper tubes to form the CuO structured surface. The tubes investigated in this study were bent into U-shapes with a total length of 30 cm, consisting of two ¼ arc sections with a radius of 1.9 cm each.

TABLE 2
Geometry specifications of the tubes.

| | | | Wall Thickness |
|---|---|---|---|
| Material with Grade | OD mm (in) | ID mm (in) | mm (in) |
| Copper 122 | 6.35 | 4.72 | 0.813 |
| | (¼) | (0.186) | (0.032) |
| Aluminum 6061 | 6.35 | 4.57 | 0.889 |
| | (¼) | (0.180) | (0.035) |

FIG. 3A illustrates the cleaning process and FIGS. 3B-3D illustrate the fabrication processes and SEM images of the etched aluminum tubes, boehmite tubes, and copper oxide tubes, respectively. Referring to FIG. 3A, prior to surface modification, all external surfaces of the specimens were cleaned using acetone (Sigma Aldrich, CAS #64-64-1), isopropanol (Sigma Aldrich, CAS #67-63-0), and deionized (DI) water to remove organic compounds. Subsequently, the tubes were dried using a clean stream of nitrogen. FIG. 3A also shows the SEM images of plain aluminum and copper surfaces, where grooves and scratches stemming from the extrusion manufacturing process contribute to their innate roughness. No micro/nanostructures were observed on the plain tubes.

For all surface modifications, a glass container with an inner diameter of 19 cm served as the reaction vessel. The etched aluminum tubes were prepared following the chemical etching procedure shown in FIG. 3B. The aluminum etching solution consisted of 400 ml of 2M HCl (Sigma Aldrich, CAS #7647-01-0), and the etching process was carried out for 15 minutes at room temperature. After etching, the etched aluminum tubes were rinsed with DI water and dried using nitrogen. This post-processing step was also employed at the conclusion of any surface fabrication in this study to ensure the cleanliness of the final tube surfaces. FIG. 3B also displays SEM images of the aluminum surface after etching, showing the presence of cavities (˜1 μm) and larger grooves (˜5 μm width and >10 μm length). These crisscrossing cavities suggest the existence of re-entrant structures, which can potentially enhance boiling performance.

The boehmite tubes were obtained by immersing the cleaned plain tubes in DI water at a constant temperature of 90° C. for one hour (FIG. 3C). The reaction temperature was controlled using a hot plate (IKA C-MAG HS 7 S001) and a thermocouple (IKA ETS-D5). In FIG. 3C, the SEM image highlights needle-shaped structures of boehmite (AlO(OH)) on the aluminum surface. It is worth noting that the size of these “needles” is smaller than the micron level, reaching nanometric length scales. These structures grow like grasses on the substrate and provide small potential cavities (˜100 nm) for boiling enhancement.

The CuO structured surface was fabricated using a chemical oxidation method, following the same initial cleaning process with acetone, isopropanol, and DI water to clean the external surface. The copper tubes were next immersed in a 400 ml 2M HCl solution for 30 seconds, with continuous stirring. This was done to remove the native oxide layer formed on the surface due to air oxidation. Subsequently, DI water was used to rinse the residual HCl from the surface, followed by drying with a clean nitrogen gas stream. Next, a 400 ml solution consisting of NaClO₂, NaOH, Na₃PO₄·12H₂O, and DI water (3.75:5:10:100 weight %) was prepared. The reaction temperature was maintained at 90° C. using a hot plate (IKA C-MAG HS 7 S001) and a thermocouple (IKA ETS-D5) (FIG. 3D). Finally, the copper tube was submerged in the solution for 8 minutes until the outer surface turned completely black. FIG. 3D showcases the CuO structure, which appears as numerous clusters of flower-like shapes in the low magnification SEM image. However, upon closer inspection at higher magnification (˜1-2 μm), the structure is revealed to be composed of stacked flakes.

The three structures exhibit distinct sizes, ranging from nanometers to tens of microns. It is important to note that the top-view SEM imaging technique provides information about the shape and size of structures in the x-y plane, while lacking information about the z-axis or height dimension. To observe structures in the z-axis, an alternative characterization technique such as confocal imaging is required.

FIGS. 4A-4F present confocal imaging (Keyence VK-X1000 3D Optical Profiler) results for the five different surfaces. In FIG. 4A, the confocal image of the plain aluminum surface reveals a height range of −3 μm to 1.7 μm. The majority of the surface appears smooth in orange color, with minimal height differences within 1 μm. The confocal image of the boehmite surface (FIG. 4B) does not clearly exhibit the distinct structures due to its smaller scale. The boehmite surface appears similar to the plain aluminum surface, with smaller height differences. Only a few raised platforms (indicated by the red area) can be observed in the image. In contrast, FIG. 4C presents a lower magnification (˜700 μm) confocal image of the etched aluminum surface, indicating significantly larger height variations compared to the plain aluminum surface. The deepest grooves reach a depth of −33μm, while the highest peaks extend to 23 μm. When observing the structure at higher magnification (˜100 μm, FIG. 4F), it is evident that the structures typically have a size of at least 10 μm.

FIGS. 4D and 4E highlight the differences between the plain copper surface and the CuO surface. The confocal image of the plain copper surface resembles the plain aluminum surface, with small height differences ranging from −1.8 μm to 1.6 μm. Most areas of the plain copper surface exhibit a smooth texture. In contrast, the CuO surface appears rougher than the plain copper surface, as evidenced by the presence of more isolated red spots in the confocal image. Additionally, the color bar representing the height variations in the CuO surface image indicates a larger-scale range of heights, spanning from −3 μm to 3 μm. Notably, surface materials (i.e. copper and stainless steel) can affect boiling performance. In this study, it was found that plain Al presents slightly higher HTCs (up to 10%) when compared to plain Cu at the same working conditions. The fundamental difference between Cu and Al can be attributed to the surface finish, where FIGS. 4A and 4D also show that the aluminum tube is slightly rougher than the copper tube. All HTC enhancement ratios were obtained based on the same materials (etched Al to plain Al, boehmite to plain Al, and CuO to plain Cu). Consequently, material was not considered as a factor in this investigation of the role of structure length scale in pool boiling HTC enhancement.

### Results

In this study, three different refrigerants, R-134a, R-1336mzz(E), and R-1336mzz(Z) were tested at two different saturation temperatures, 20° C. and 30° C.

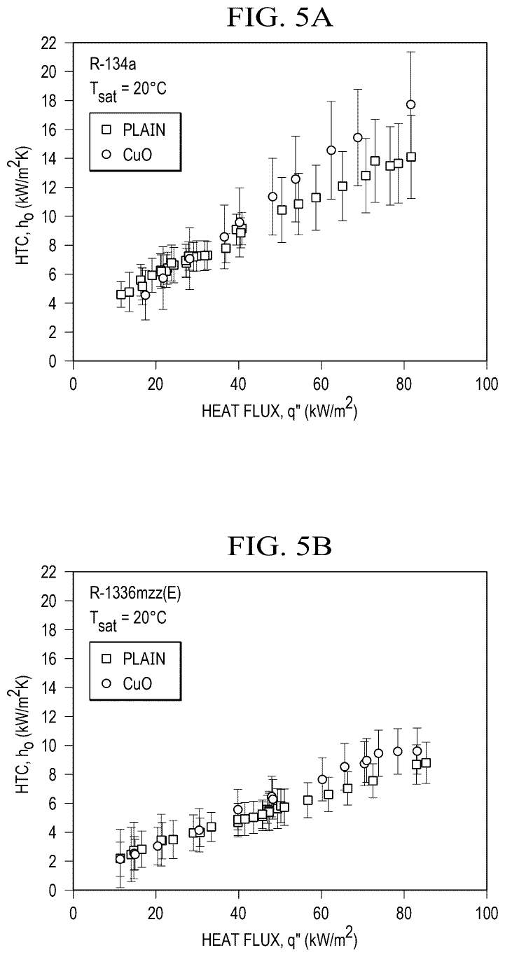

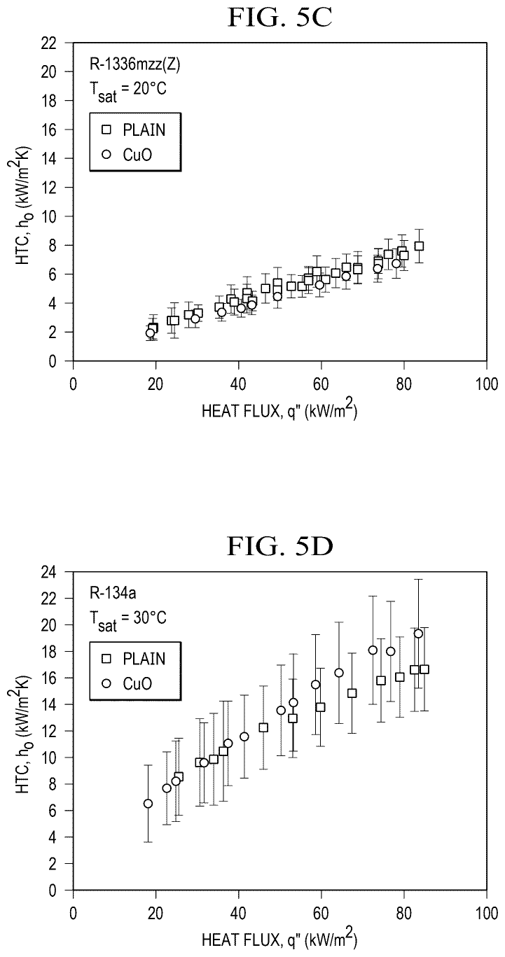

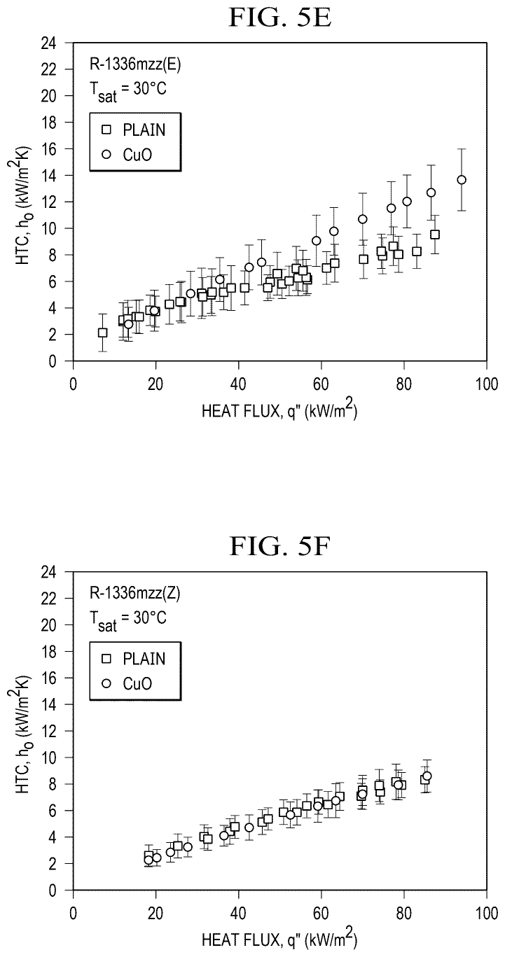

FIGS. 5A-5F depict the pool boiling performance of the three different refrigerants on plain and CuO structured copper tubes at two saturation temperatures: 20° C. and 30° C. All curves show a higher HTC with higher heat flux due to the activation of more nucleation sites at higher wall superheat (higher heat flux). In general, R-1336mzz(Z) exhibited the lowest HTC, while R-134a showed the highest HTC at the same heat flux. This discrepancy is mainly attributed to the reduced pressure difference among the refrigerants, with R-134a having the highest reduced pressure (Pᵣ=0.1409 at 20° C.), followed by R-1336mzz(E) (Pᵣ=0.05943 at 20° C.) and R-1336mzz(Z) (Pᵣ=0.02071 at 20° C.). According to Cooper's model, higher reduced pressure leads to higher HTC, and consequently, a higher saturation temperature (30° C.) also results in a higher HTC (FIGS. 5D-5F). In general, when pressure increases, the nucleate boiling theory shows the wall superheat required to activate a given size cavity becomes smaller because of the reduced surface tension and increasing vapor density. Interestingly, when comparing pool boiling HTC data for plain tubes between R-1336mzz(E) and R-1336mzz(Z), the differences are negligible, where HTC of R-1336mzz(E) slightly exceed that of R-1336mzz(Z) despite the large difference in reduced pressure. This can be explained by the low reduced pressure of R-1336mzz(Z); the sensitivity of HTC to heat flux increases at low reduced pressure.

Analyzing the data points for the CuO surface structured copper surface, it is evident that at low heat fluxes (q″<40 kW/m²), the CuO structures do not exhibit an enhancement and may even slightly inhibit boiling performance. However, when the heat flux increases (q″>50 kW/m²), the HTC of the CuO surface starts to outperform that of the plain copper surface for R-134a (FIGS. 5A and 5D) and R-1336mzz(E) (FIGS. 5B and 5E), where the enhancement can reach up to 25% at high heat flux. In contrast, the CuO surface does not have any enhancement for R-1336mzz(Z), as its boiling curve almost overlaps with that of the plain copper surface (FIGS. 5C and 5F). Although on plain copper tubes, R-1336mzz(E) and R-1336mzz(Z) have similar HTC results, this changed on the CuO tubes, indicating that the refrigerant thermophysical properties play a role on the HTC enhancement. The results indicate that the new cavities created by the CuO surface are too small (<1 μm) to be activated for R-1336mzz(Z) within the range of wall superheat tested but are suitable for R-1336mzz(E) at higher wall superheat (higher heat flux).

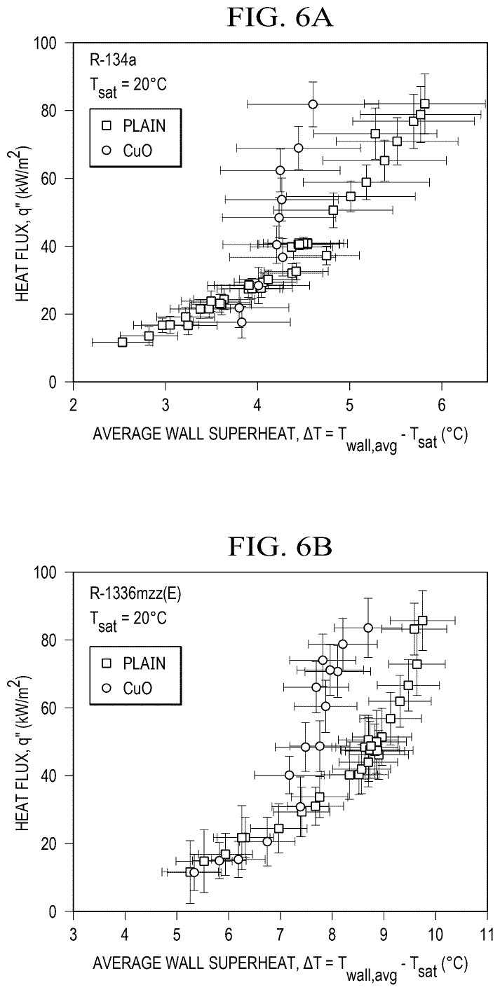

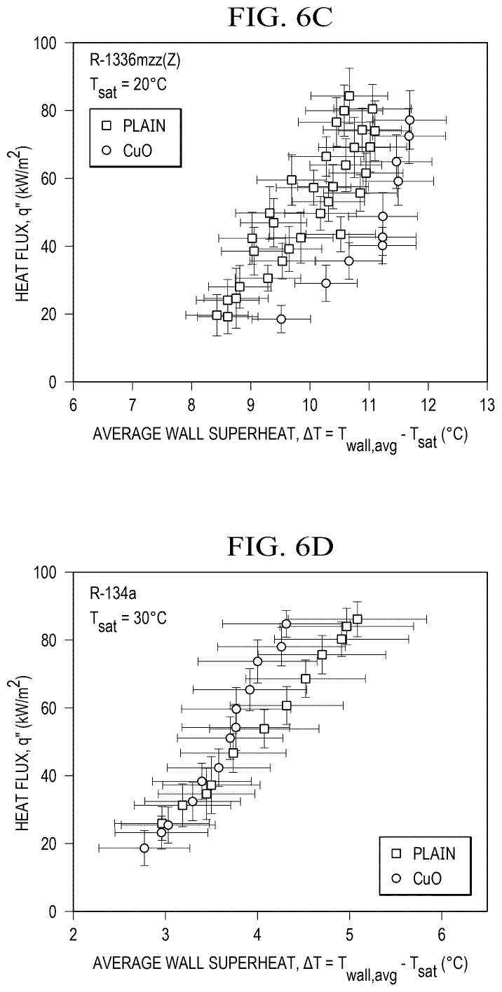

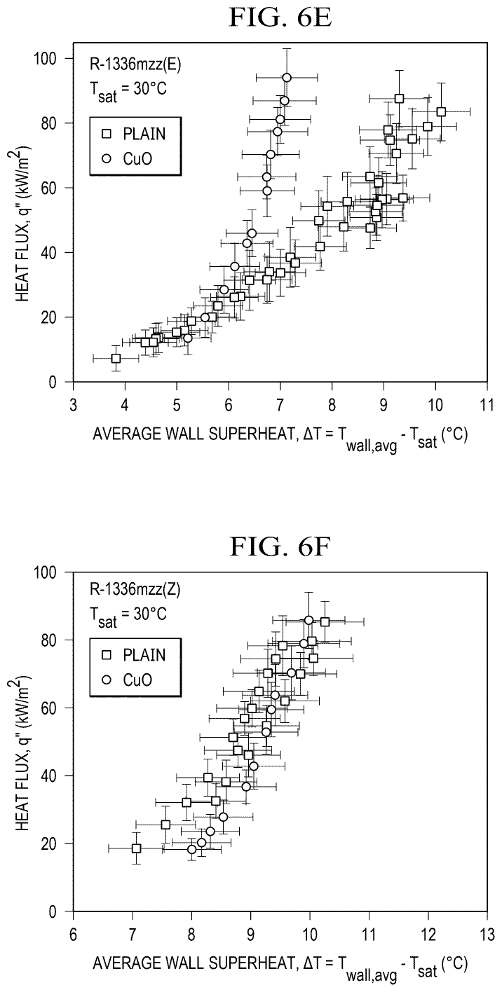

FIG. 6A-6F present the relationship between heat flux (q″) and average wall superheat (ΔT). The average wall superheat is calculated as:

$$Δ T = {T}_{wall , avg} - {T}_{s a t} = \frac{{q}^{″}}{{h}_{o}} . \qquad ( 2 )$$

For all three refrigerants, the figures show that higher saturation temperature (Tₛₐₜ) can reduce the required wall superheat (ΔT) at the same heat flux (q″), where higher reduced pressures result in higher HTC at the same heat flux. For refrigerants R-134a and R-1336mzz(E), the CuO sample starts to show lower wall superheat when the heat flux exceeds 40 kW/m², indicating that more potential nucleation cavities have been activated at the same wall superheat when compared to plain copper tubes. However, refrigerant R-1336mzz(Z) behaves differently where similar or even higher wall superheats are required to achieve the same heat flux when compared to plain copper tubes. The results show that the new cavities created by CuO structure (<1 μm) are inactive for R-1336mzz(Z), and consequently it shows similar HTC data as plain copper samples.

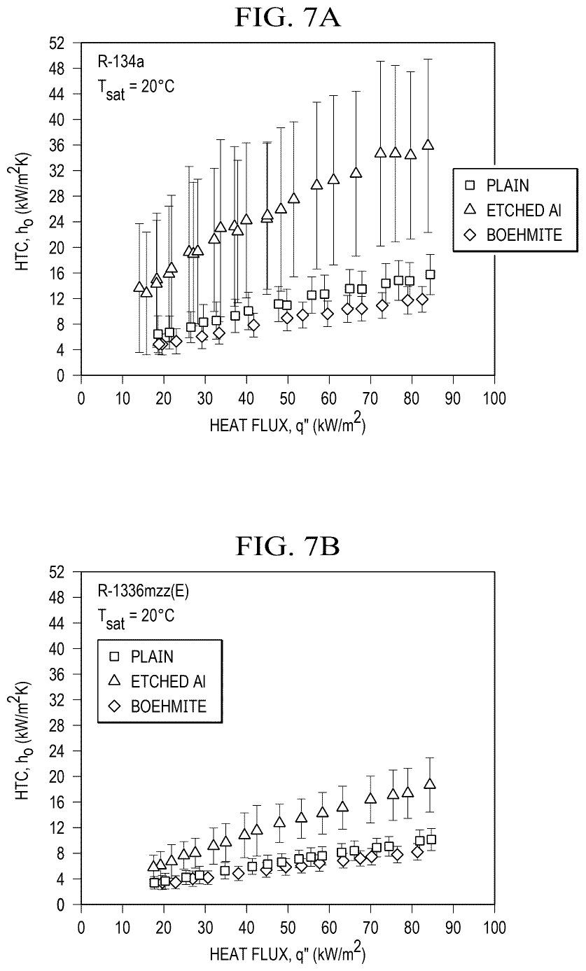

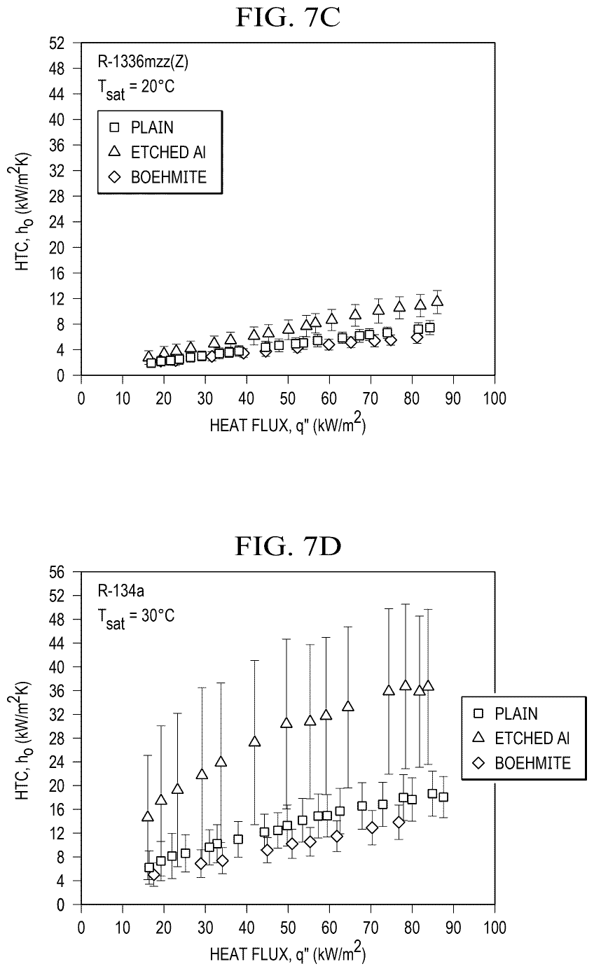

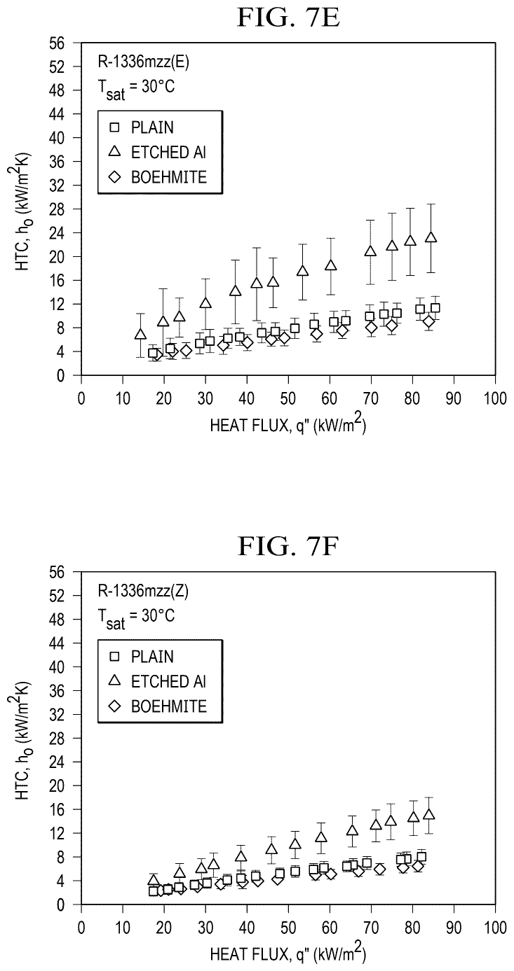

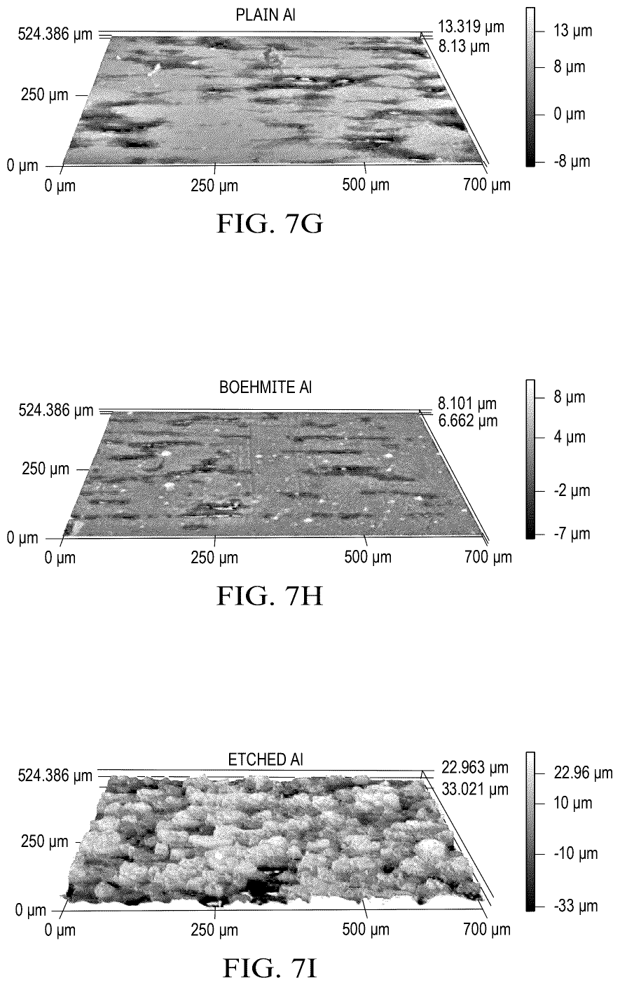

FIGS. 7A-7I show the pool boiling HTC on plain and structured (boehmite and etched) aluminum tubes as a function of applied heat flux. FIGS. 7A-7C correspond to a saturation temperature of 20° C., while FIGS. 7D-7F correspond to a saturation temperature of 30° C. Like FIGS. 5A-5F, at the same heat flux, the HTCs are highest for R-134a and lowest for R-1336mzz(Z) due to the reduced pressure difference. The etched aluminum surface exhibited a significant enhancement in HTC when compared to the plain aluminum tube, reaching up to 250% for R-134a, 175% for R-1336mzz(E) and up to 150% for R-1336mzz(Z). The boehmite surface actually demonstrated a decrease in the boiling performance with lower HTC values across most heat fluxes when compared to the plain aluminum tube. This enhancement and inhibition can be attributed to the differences between the surface structure length scale.

FIGS. 7G-7I provide confocal images of the surface geometries at low magnification. It is notable that the boehmite surface appears smoother than the plain aluminum surface, with lower maximum peak height and groove depth. Most of the boehmite surface has a height range of −1 μm to 0 μm, whereas the plain aluminum surface exhibits larger color variation, suggesting the presence of more potential cavities within the desired size range. Despite the needle-like structures observed by SEM (cavities sized at 500 nm or smaller), the boehmite structure does not contribute to pool boiling enhancement. Instead, the fabrication process makes the surface smoother in general and inhibits boiling due to the addition of numerous nucleation sites which are too small to be activated at reasonable wall superheat. In contrast, FIG. 7I displays significant roughness on the etched aluminum surface, with larger cavities (>10 μm) that are more favorable for pool boiling with all three tested refrigerants.

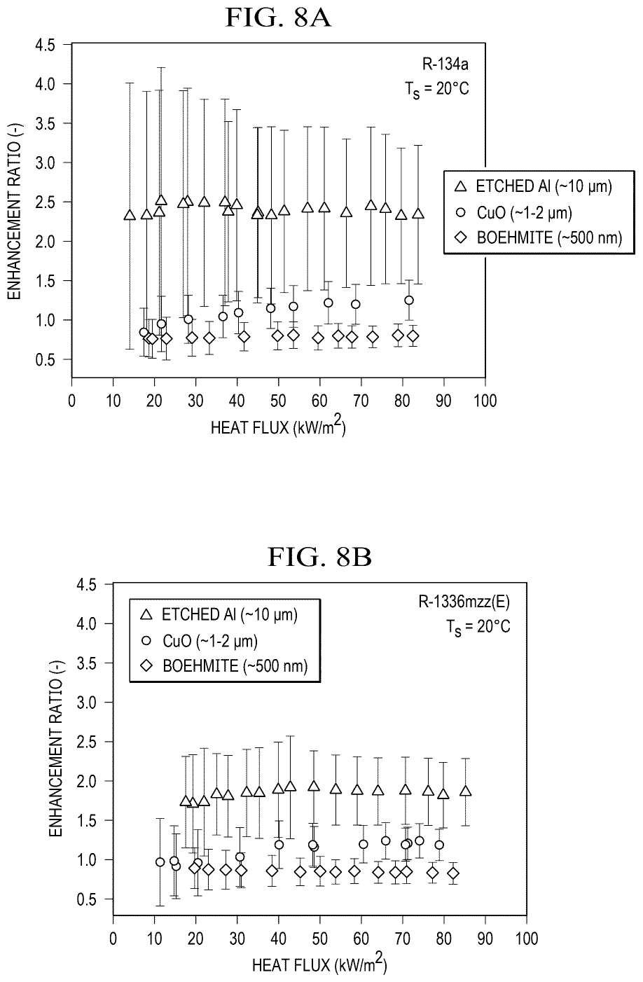

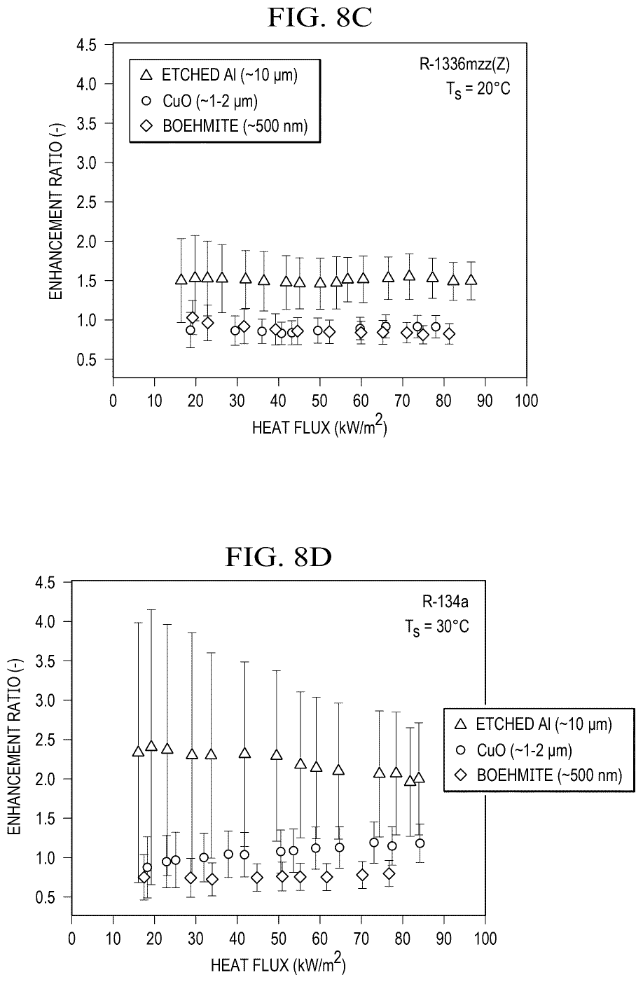

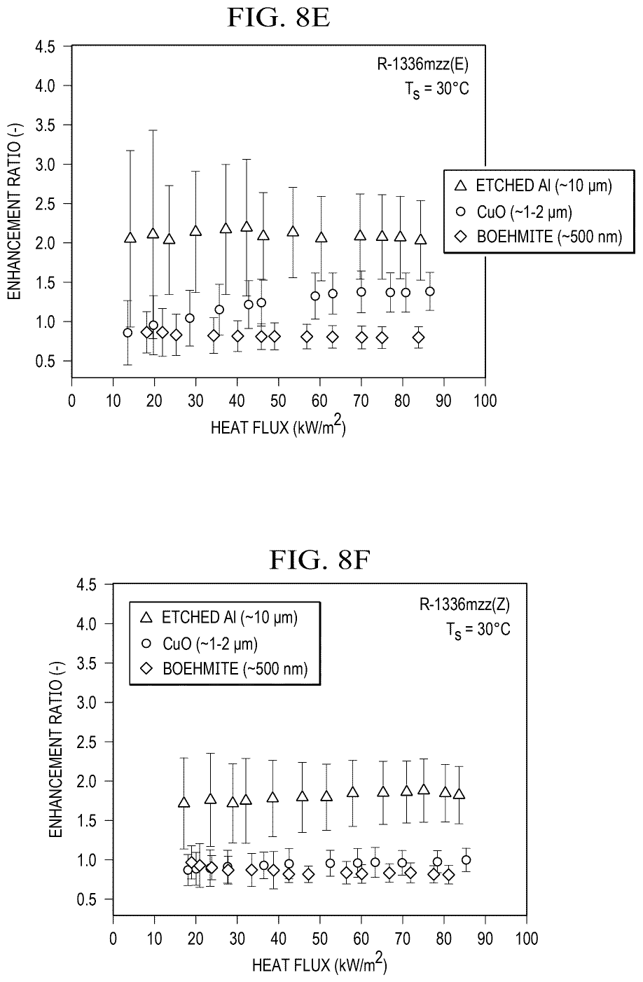

To further investigate the relationship between micro/nanostructure length scale and pool boiling HTC enhancement, an enhancement ratio is introduced as a ratio of the structured tube HTC (h_{o,structured}) to the plain (unetched) tube HTC (h_{o,plain}):

$$φ = \frac{{h}_{o , structured}}{{h}_{o , plain}} , \qquad ( 3 )$$

where the h_{o,plain} data was interpolated using fitted 4th order polynomial curves obtained from the plain tube data. FIGS. 8A-8F illustrate the HTC enhancement ratio (φ) as a function of heat flux (q″) on the different structured tubes. For R-134a (FIGS. 8A and 8D), the etched aluminum surface enhances the HTC by 150% ( φ_{etched Al}≈2.5), while the CuO surface provides up to 25% enhancement (φ_{CuO}≈1.25) at higher heat fluxes (q″>40 kW/m²). However, the boehmite surface inhibits the boiling HTC by approximately 25% across all heat fluxes (φ_{boehmite}≈0.75). In the case of R-1336mzz(E) (FIGS. 8B and 8E), the etched aluminum surface can enhance HTC up to 75% when compared to the plain aluminum surface (φ_{etched Al}≈1.75), while the CuO surface exhibits 25% enhancement at high heat fluxes (φ_{CuO}≈1.25). On the other hand, the boehmite surface decreases HTC by 15% (φ_{boehmite}≈0.85). For R-1336mzz(Z) (FIGS. 8C and 8F), both the boehmite and CuO surfaces slightly decrease boiling HTC by 5 to 10% at all tested heat fluxes. However, the etched aluminum surface continues to enhance HTC by up to 50% for all heat fluxes (φ_{etched Al}≈1.5). Notably, with the same refrigerant, the trends of enhancement ratios on different structured tubes are similar, where etched aluminum outperforms copper oxide, which outperforms boehmite nanostructures.

However, for the same structured tube, the enhancement ratios are different depending on the different refrigerants used. In the case of etched aluminum tubes, R-134a exhibited the highest enhancement ratio (φ_{etched Al}≈2.5), followed by R-1336mzz(E) (φ_{etched Al}≈1.75), and R-1336mzz(Z) (φ_{etched Al}≈1.5). These enhancement ratios remain consistent at different heat fluxes. Conversely, for the CuO surface, φ_{CuO} increases with heat flux for R-134a and R-1336mzz(E), ranging from φ_{CuO}≈0.9 at low heat flux to φ_{CuO}≈1.25 at high heat flux. It suggests that the CuO surface creates cavities with varying sizes, so that smaller cavities will be activated at higher heat fluxes (with higher wall superheat). In contrast, the cavity sizes on etched aluminum remains relatively stable, large, and easy to activate at even the lower wall heat fluxes (superheat), resulting in φ_{etched Al} remaining unchanged with heat flux/wall superheat. These larger size cavities can be activated at the onset of boiling and can keep trapping vapor at different wall superheats. A notable case is R-1336mzz(Z) on the CuO surface, where no HTC enhancement and even HTC degradation was observed when compared to the plain copper surface. The result indicates that the cavities made with the CuO structure will are not activated on R-1336mzz(Z) within the wall superheat range tested here. Interestingly, when considering the boehmite surface, R-134a exhibits the largest HTC decrease while R-1336mzz(Z) shows the lowest decrease. This is because for R-134a, numerous potential cavities on the plain surfaces were removed by the boehmite fabrication step. On the other hand, R-1336mzz(Z) does not have many active cavities on plain surface since it has thermophysical properties which have a larger critical nucleation cavity size. Consequently, more potential cavities were eliminated for R-134a when compared to R-1336mzz(Z), resulting in a higher HTC inhibition.

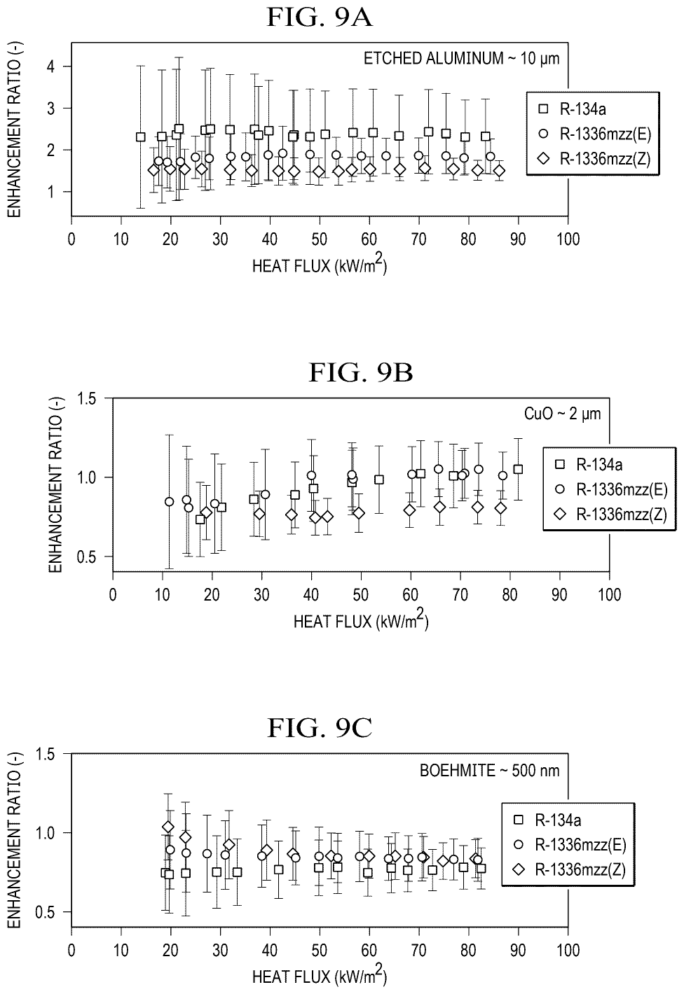

FIGS. 9A-9C show plots depicting the direct comparison for HTC enhancement ratios with different refrigerants on the same structured tubes. The difference of enhancement ratio among the different refrigerants can be attributed to refrigerant thermophysical properties, which is discussed next.

To better understand the effect of refrigerant thermophysical properties on the pool boiling performance, video analysis of the pool boiling process was conducted through the optical viewports on the experimental chamber (FIG. 2A). Visualizations of pool boiling were captured by a high-speed camera (Mini AX200, Photron FASTCAM), where three different refrigerants boil on the 0.25″ outer diameter plain aluminum tube at various heat fluxes. The departure bubble size can be observed, with R-134a producing the smallest bubbles, followed by R-1336mzz(E) with larger bubbles, and R-1336mzz(Z) with the largest bubbles. Isolated bubbles are observed at low heat flux, while more bubbles merge at higher heat fluxes, making it difficult to distinguish individual bubbles. The bubble departure diameters at q″=25 kW/m² were quantified by manually measuring the 2D projected surface area of bubbles in the field of view. Photoshop was used as a tool to post-process the images obtained by the high-speed camera. A scale bar was first set using the diameter of the tube (6.35 mm). An image area of 200 by 200 pixels was chosen for measuring the 2D projected area in the field of view. Using the magnetic lasso tool, each bubble area was manually selected in the region of analysis. Each selected bubble area was measured and recorded by Photoshop. Then the average area of bubble was calculated as A_{bubble,avg}=Total 2D bubble area/Number of bubbles. By knowing the average 2D projected area of departure bubbles (A_{bubble,avg}), the effective bubble departure diameter was calculated as:

$${D}_{departure} = 2 \sqrt{\frac{{A}_{b u b b l e , a v g}}{π}} . \qquad ( 4 )$$

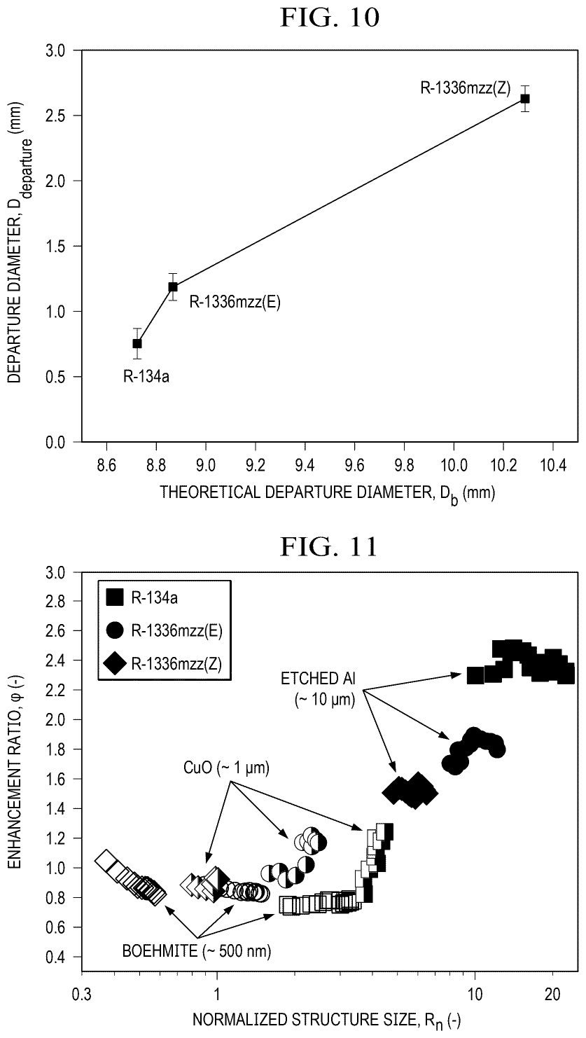

The obtained diameters are shown in Table 3. The theoretical bubble departure diameter (D_{b}) can be scaled to the properties of the refrigerant using the equation:

$${D}_{b} ∼ {[ \frac{σ}{g ( {ρ}_{1} - {ρ}_{v} )} ]}^{\frac{1}{2}} , \qquad ( 5 )$$

where σ is the liquid-vapor surface tension of the refrigerant, g is the gravitational acceleration, ρₗ and ρᵥ are liquid density and vapor densities, respectively. While the liquid densities of the refrigerants are similar, the major differences among refrigerants are their surface tensions and vapor densities (Table 1). FIG. 10 shows the measured departure diameter can be scaled to a theoretical characteristic length scale, eq. 5. Larger surface tension can result in larger departure bubble size, where R-1336mzz(Z) has the largest bubble and R-134a has the smallest. Properties of the refrigerants can be found in Table 1.

TABLE 3
Measurements of departure bubble sizes.

| | Number of | Average | Average |
|---|---|---|---|
| | bubbles | surface area, | diameter, |
| Refrigerant | analyzed | A_{bubble, avg} [mm²] | D_{departure} [mm] |
| R-134a | 99 | 0.4452 ± 0.138 | 0.7529 ± 0.117 |
| R-1336mzz(E) | 44 | 1.1018 ± 0.196 | 1.1844 ± 0.105 |
| R-1336mzz(Z) | 18 | 5.4267 ± 0.403 | 2.6286 ± 0.098 |

While all three refrigerants have similar liquid to vapor density differences (Table 1), Eq. 5 shows that surface tension plays a key role on the size of departing bubbles from the surface. The bubble departure size difference between each refrigerant is key in helping to explain the HTC differences observed on the plain Al and plain Cu tubes. However, the bubble departure diameter analysis fails to tell the complete story. Departure diameter does not explain differences in nucleation cavity sizes nor their active site distributions and cannot relate to the structure size. Although surface structured so act to enhance wettability and decrease the contact line length, all the surface structures used in this study resulted in wettability increase and spherical bubble generation on the tube surface.

To understand the role that structure size plays in HTC enhancement, the bubble critical nucleation radius is investigated. From the Clausius-Clapeyron relation it is known:

$$Δ T = \frac{2 σ {T}_{s a t} ( {v}_{v} - {v}_{1} )}{{R}_{nucleation} {h}_{f g}} \approx \frac{2 σ {T}_{s a t}}{{R}_{nucleation} {ρ}_{v} {h}_{f g}} , \qquad ( 6 )$$

where νᵥ>>νₗ is assumed (Table 1), ΔT is the temperature difference required to create a stable bubble of radius R_{nucleation}, Tₛₐₜ is the saturation temperature, ρᵥ is the vapor density, and h_{fg} is the latent heat of boiling. By re-writing Eq. (6), the critical bubble nucleation radius can be expressed as:

$${R}_{n u c l e a t i o n} = \frac{2 σ {T}_{s a t}}{Δ T {ρ}_{v} {h}_{f g}} . \qquad ( 7 )$$

Equation (7) indicates that at higher wall superheat ΔT, smaller cavities can be activated. However, the surface tension σ, vapor density ρᵥ and liquid-to-vapor latent heat of phase change h_{fg} also impact the critical bubble nucleation radius. To account for the effects of refrigerant properties, a normalized structure size is introduced as:

$${R}_{n} = \frac{{R}_{structure}}{{R}_{nucleation}} \qquad ( 8 )$$

Here, R_{structure} represents the cavity size observed from SEM and confocal analysis. For the surfaces studied here, R_{structure}=10 μm, 1 μm and 500 nm, for etched Al, CuO and boehmite surface structures, respectively. The critical nucleation radius R_{nucleation} is calculated using Eq. (7) assuming ΔT is the average wall superheat obtained from the experimental results. Different working conditions yield varying nucleation radii.

FIG. 11 plots the HTC enhancement ratio as a function of normalized structure size (Rₙ) for the preliminary data obtained here; a more complete plot is shown in FIG. 17, which is described below. Each set of data was obtained in a range of heat fluxes from 20 kW/m² to 90 kw/m². At lower Rₙ, typically when Rₙ<4, no HTC enhancement is observed, and in some cases inhibition occurs. However, when Rₙ>4, the enhancement ratio starts to increase rapidly with Rₙ. This trend is consistent for all three refrigerants depicted in FIG. 11. Similarly, for the same tube structure size, FIG. 11 illustrates that higher Rₙ can result in higher HTC enhancement ratio, when accounting for the effects of refrigerant properties.

### Preparation and Characterization of Etched Surfaces (Example 2)

Additional experiments were carried out with copper tubes etched using a new procedure capable of producing microscale cavities.

The experimental tubes were 0.25″ Dₒ commercial copper (McMaster, 8967K88, 122 grade) with 0.186″ Dᵢ, deoxidized with phosphorus, offering compatibility with heavy forming processes like tube manufacturing. Mechanically akin to 110, 122 copper provides excellent corrosion resistance, formability, weldability, and brazing capabilities, commonly used in pipes and tubing. The tubes investigated in this study were bent into U-shapes with a total length L of 30 cm. The cleaning process for the plain tubes involved first sonication with acetone (Sigma-Aldrich, CAS No. 64-64-1), followed by rinsing with isopropanol (IPA, Sigma-Aldrich, CAS No. 67-63-0) and deionized (DI) water. The fabrication methods for the two types of etched Cu tubes are illustrated in FIGS. 12A-12D, encompassing both pre-processing and post-processing. To safeguard against chemical infiltration during fabrication, both ends of the copper tubes were sealed using compression stainless steel hex caps (5182K634, McMaster-Carr). The cleansing protocol, as delineated in FIG. 12A, involved sequential rinsing of the external surfaces with acetone, IPA, and DI water. Subsequently, the tubes underwent further cleansing in 2M hydrochloric acid (HCl, Sigma-Aldrich, CAS No. 7647-01-0, 37% wt.) and were then rinsed with DI water and IPA before drying in a stream of clean nitrogen gas.

The preparation of the externally etched Cu tubes used two distinct chemical etching methodologies, depicted in FIGS. 12B and 12C and referred to as Recipe I and II herein. Recipe I entailed submerging the tube in a mixture of HCl and hydrogen peroxide (H₂O₂, Sigma-Aldrich, CAS No. 7722-84-1, 50% wt.) in a 1:7.5 volume ratio for a 24-hour duration. Recipe II involved a 5.5-hour etching in a ferric chloride (FeCl₃, CESCO, 43% wt.) and HCl mixture with the same volumetric proportions (1:7.5). Unlike previous studies which have focused on nanoscale roughness features, which are known to be too small for boiling cavity activation, the new etching recipes create roughness features that are much larger in length scale, exceeding 10 μm. Post-etching is shown is FIG. 12D, where the structured external surfaces of the copper tubes were sonicated in DI water for 10 minutes and then sequentially cleansed with acetone, ethanol, and IPA to eliminate any residual chemicals on the surface, ensuring that the surface consisted of pure copper. The hex caps were then removed from the tube ends, preparing them for installation into the chamber. For ease of differentiation, the etched Cu tubes produced by Recipe I and II are referred to in the following description as the H₂O₂ Etched Cu and the FeCl₃ Etched Cu, respectively.

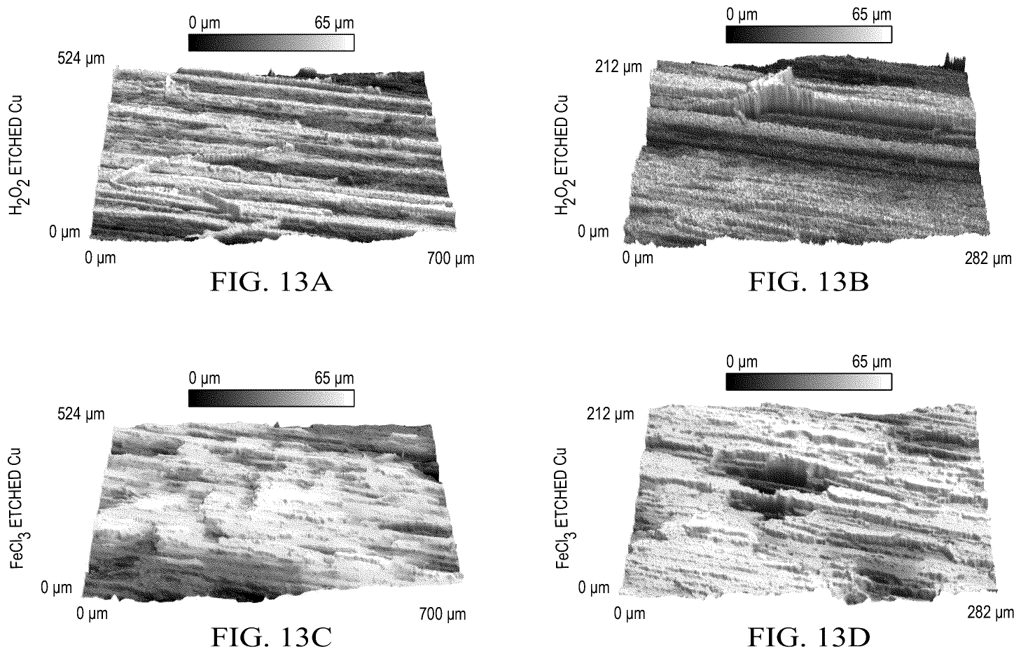

Confocal (Keyence VK-X1000 3D Optical Profiler) and SEM surface characterization of the untreated plain Cu tubes are presented in FIG. 12A, with the SEM of the two etched Cu tubes shown in FIGS. 12B and 12C, revealing striped patterns resulting from the two different etching methods. Both etching methods share a common approach: utilizing the oxidizing nature of H₂O₂ and FeCl₃ to oxidize parts of the copper tube, followed by using hydrochloric acid to remove the oxidized layer, thus imparting a certain similarity to their structures. In this reaction, hydrogen peroxide and ferric ions are reduced to water and ferrous ions, respectively, while copper is oxidized into copper ions in the acidic environment. The stripes naturally arise due to the fabrication method of the Cu tubes, which involves extrusion of Cu in the axial direction of the tube. In addition to facilitating larger scale structures which are optimal for boiling, the use of etching is also advantageous from a reliability standpoint. Many prior techniques have utilized oxidation methods to create roughness features, where a thin oxide layer forms the roughness and bonds precariously to the pure metal substrate. Any reducing agent in the working fluid can result in feature removal (via reduction of the oxide) and thermomechanical stress at the oxide-metal interface poses a challenge for long term operation. The etching approach used here avoids these challenges by forming larger scale metallic features which are more resilient. FIG. 13A illustrates the large-scale striped structure of the H₂O₂ Etched Cu tube, with the maximum peak-to-valley height difference being 62 μm. FIG. 13B depicts a magnified view of the small-scale structure on the H₂O₂ Etched Cu tube, showing irregular striped protrusions with distinct variations in height across the surface. The large-scale characterization of the FeCl₃ etched tube is presented in FIG. 13C, showcasing similar striped structures with a slightly larger peak-to-valley height (depth) difference than the H₂O₂ etched tube, at 65 μm. The protrusions on the FeCl₃ Etched Cu tube are not as sharp as those on the H₂O₂ etched tube. Its magnified characterization is shown in FIG. 13D, where the irregular surface exhibits peaks and deep valleys.

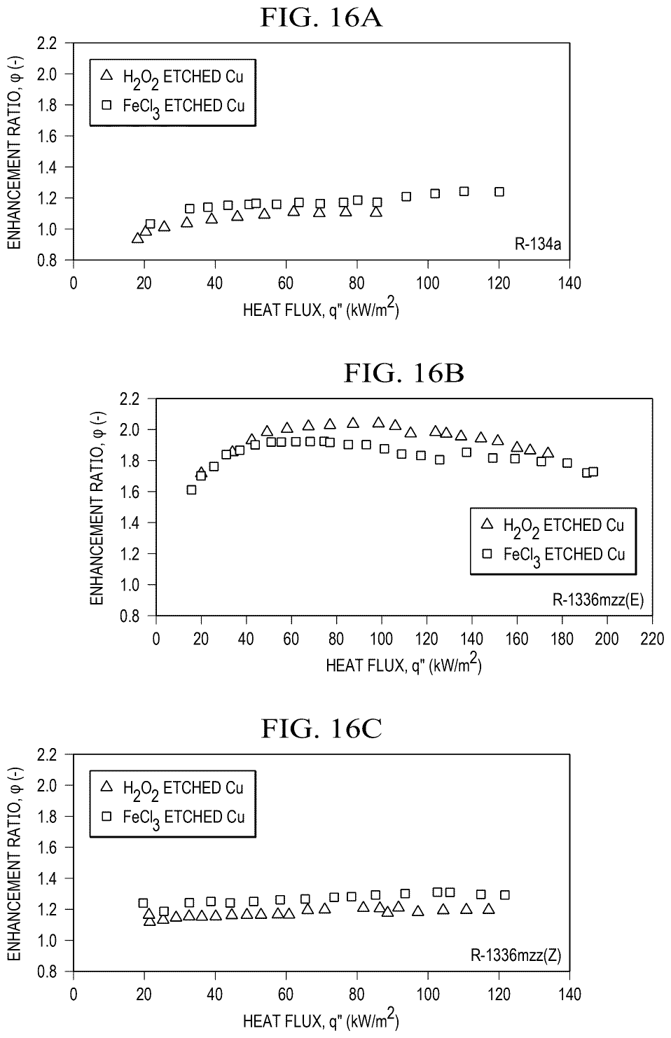

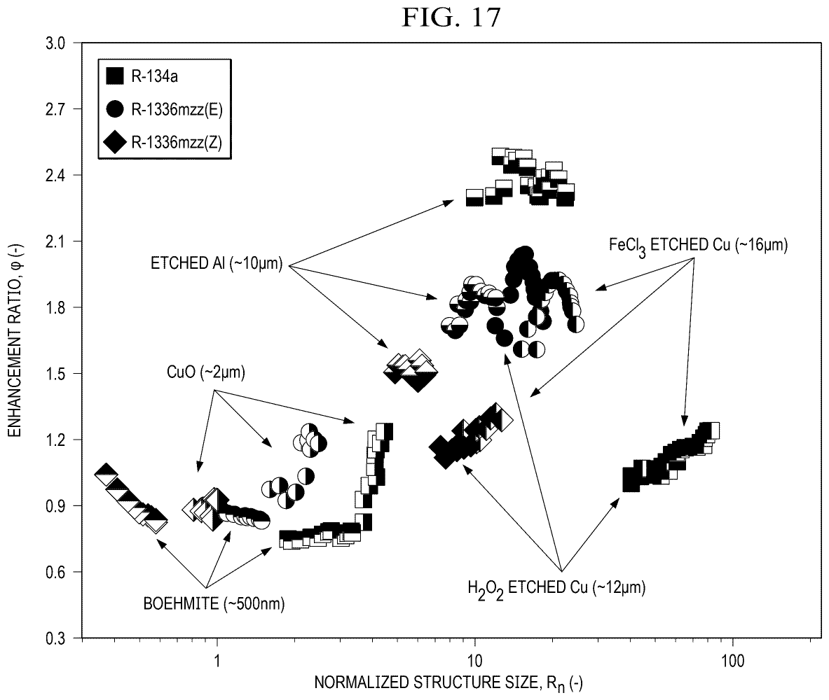

The pool boiling HTC as a function of heat flux (hₒ vs. q″) curves for two types of modified surfaces, along with plain Cu tubes with the three refrigerants (R-134a, R-1336mzz(E), and R-1336mzz(Z)), at a saturation temperature Tₛₐₜ of 20° C., are presented in FIGS. 16A-16C. Heat flux q″ and external boiling HTC hₒ are calculated using known equations. As depicted in the curves, all reside in the nucleate boiling region, where the maximum heat flux for boiling for the two modified surfaces with the two low-GWP refrigerants (R-1336mzz(E) and R-1336mzz(Z)) corresponds to their critical heat flux. The critical heat flux densities of both the FeCl₃ and the H₂O₂ Etched Cu tubes are similar for the same refrigerant, being approximately 185 kW/m² for R-1336mzz(E) and 125 kW/m² for R-1336mzz(Z). The two modified surfaces exhibit varying degrees of enhancement across the three different refrigerants, meaning they have higher HTC at the same heat flux q″ when compared to the unmodified surface. In the case of R-134a, the difference in HTC at the same heat flux q″ is not significant, with curves for the plain surfaces and modified surfaces nearly overlapping at low heat fluxes (q″<40 kW/m²). However, at higher heat fluxes (q″>60 kW/m²), both the H₂O₂ and the FeCl₃ Etched Cu tubes show greater boiling enhancement, with the modified surface boiling curves gradually diverging from the plain surface curves. Moreover, the heat transfer performance of the FeCl₃ etched tube is slightly superior to that of the H₂O₂ etched tube. The significant increase in HTC on the modified surfaces at high heat fluxes is due to the activation of smaller cavities at high degrees of wall superheat typical of high heat flux conditions. With R-1336mzz(Z), both modified surfaces exhibit similar performance, showing results akin to the plain Cu tubes at low heat fluxes (q″<40 kW/m²) and a modest enhancement at higher heat flux (q″>60 kW/m²). The enhancement of the two etched surfaces with R-1336mzz(Z) is like that observed with R-134a.

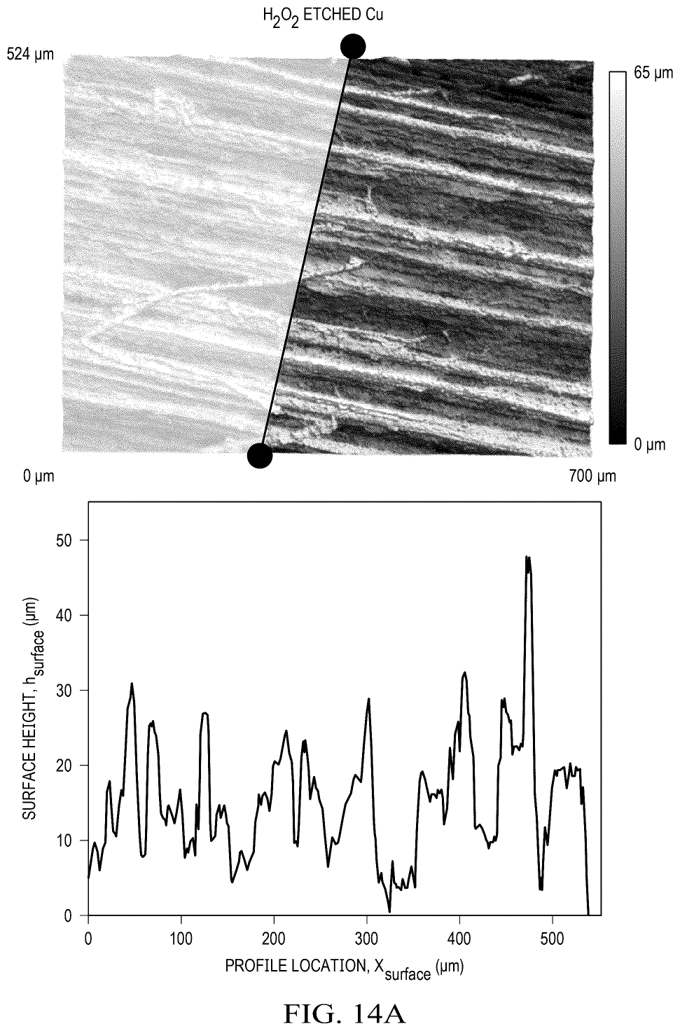

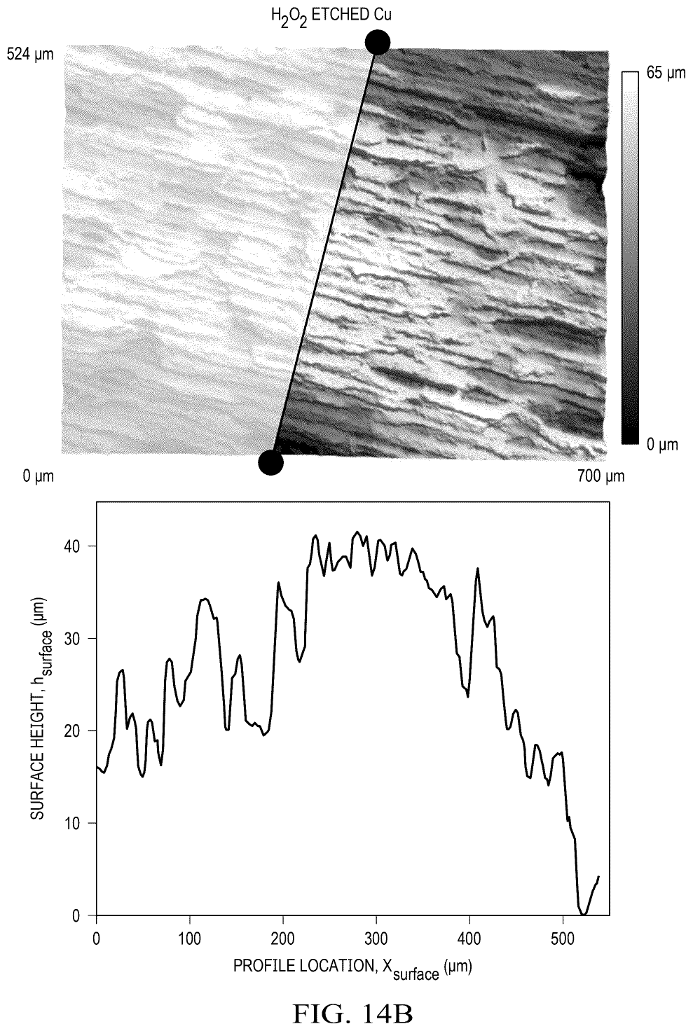

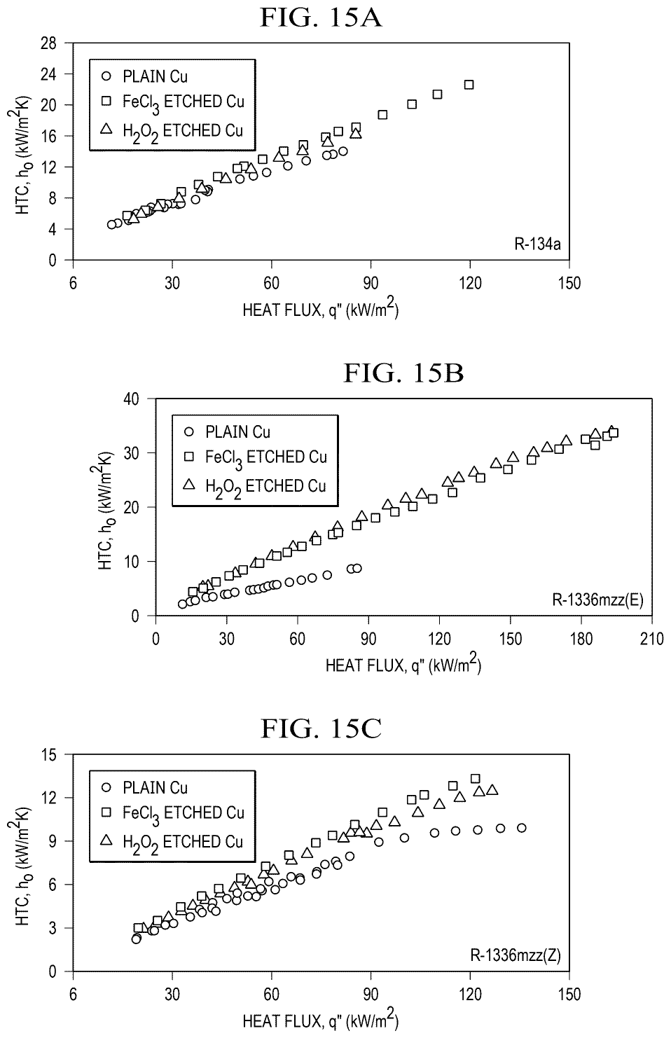

The enhancement ratios of the two modified surfaces versus the heat flux in various refrigerants are also presented in FIGS. 16A-16C, where the enhancement ratio is derived from Eq. 3. It is evident that for all refrigerants, the structured or modified surfaces exhibit enhanced HTC. However, for R-134a, the enhancement of both etched Cu tubes is modest. The H₂O₂ Etched Cu tube shows less than 5% enhancement at low heat flux (q″<30 kW/m²), increasing to 10% at a heat flux (q″=100 kW/m²). The FeCl₃ Etched Cu tube started with a 10% enhancement at low heat flux (q″<30 kW/m²), which exceeds 20% as the heat flux increases to q″=120 kW/m². The enhancement ratio φ of modified surfaces is slightly higher with R-1336mzz(Z), with the FeCl₃ and the H₂O₂ Etched Cu tubes reaching enhancement ratios of up to 1.3 and 1.2, respectively, at high heat fluxes (q″=125 kW/m²). Like the trend with R-134a, the enhancement ratio φ is positively correlated with heat flux q″ and approximates a linear increase with rising heat flux q″. The variation of the enhancement ratio with heat flux can be explained by the difference in the cavity size distribution of the modified surfaces. As observed from FIGS. 14A and 14B, compared to physical treatments like laser processing, the cavity size distribution on chemically etched surfaces is not uniform. On the etched Cu tube surfaces developed here, there are a significant number of structures smaller than the average size. Cavities with smaller curvature typically require more energy to activate. Under high heat flux conditions, the activated cavities provide more nucleation sites for boiling, enhancing the boiling process. The enhancement ratio φ of modified surfaces with R-1336mzz(E) is the highest obtained in this study. At low heat flux q″, both etched surfaces exhibit a 60% enhancement when compared to the plain Cu tube. The H₂O₂ Etched Cu tube enhancement is 20% higher than that of the FeCl₃ Etched Cu tube around a heat flux of q″=100 kW/m² with the enhancement ratios reaching up to 2.0. At higher heat flux (q″=185 kW/m²), the performance of the H₂O₂ etched and the FeCl₃ etched surfaces is similar, likely due to the deactivation of certain nucleation sites or changes in wettability, with the enhancement ratio decreasing to 2.0. It is worth noting that the enhancement ratio observed in this study may not directly translate to the enhancement ratio of commercial shell-and-tube heat exchangers utilizing the two types of etched Cu surfaces at scale. In general, the experimental conditions of this study are suited to exploring boiling mechanisms and defining new surface enhancements in boiling. Both types of etched Cu surfaces can be widely scaled for use in commercial shell-and-tube heat exchangers. The enhancement ratio obtained from this study can serve as a reference for the performance improvement of modified heat exchangers.

FIG. 17 displays the trend of the enhancement ratio φ (Eq. 3) as a function of the normalized structure size Rₙ (Eq. 8). Each data set represents the experimental results of a modified surface under different heat flux (q″) conditions with a single refrigerant. The data for etched aluminum, oxidized copper, and boehmite are from previous work. Plotting of the previous results aids in better revealing how the enhancement ratio φ varies with normalized structure size Rₙ. Overall, the enhancement ratio of structured surfaces tends to increase with the increase of normalized structure size. For Rₙ<4, the boiling enhancement is not pronounced. As Rₙ increases, boiling intensifies with increased structure size. Around Rₙ=15, the enhancement ratio reaches its maximum value of approximately 2.4.

It is noteworthy that, according to Hsu's classical nucleation theory, the enhancement ratio φ of boiling does not monotonically increase as the Rₙ increases. When the cavity radius becomes too large, and the vapor superheat required for bubble nucleation on the surface exceeds the liquid superheat available by superheating, the nucleation density on the boiling surface decreases, leading to a reduction in heat flux and corresponding enhancement ratio. However, when the enhanced structures on the boiling surface are large enough to penetrate the thermal boundary layer, the microscale boiling heat transfer enhancement model is no longer applicable. At this point, the enhanced structures can be approximated as microfins on a boiling tube. This transition is not abrupt. In fact, as the size of the structures increases, the heat transfer ratio is simultaneously influenced by both the activation of cavities and the additional heat transfer area. As the structure size approaches the thermal boundary layer thickness length scale, alteration in heat transfer performance is a process influenced by the interplay of these two contrasting trends. Overall, according to current theory, as Rₙ increases, the enhancement ratio φ should exhibit a trend of first increasing, then decreasing, and then increasing again. In this study, a decrease in the enhancement ratio was captured for both types of etched Cu tubes when boiling in R-134a. Due to its low surface tension and high vapor density (σ=8.92 mN/m and ρᵥ=27.8 kg/m³ at 20° C.), R-134a has a smaller bubble detachment diameter and can activate smaller nucleation sites. Because R-134a is the least tolerant to large-sized structures that have not penetrated the thermal boundary layer among the three refrigerants, its nucleation density often decreases before the other two low-GWP refrigerants. The observed reduction in enhancement ratio corresponds to an Rₙ of 35. Whether this reduction is due to excessively large structure sizes requires further verification with experiments using enhanced tubes with larger structures.

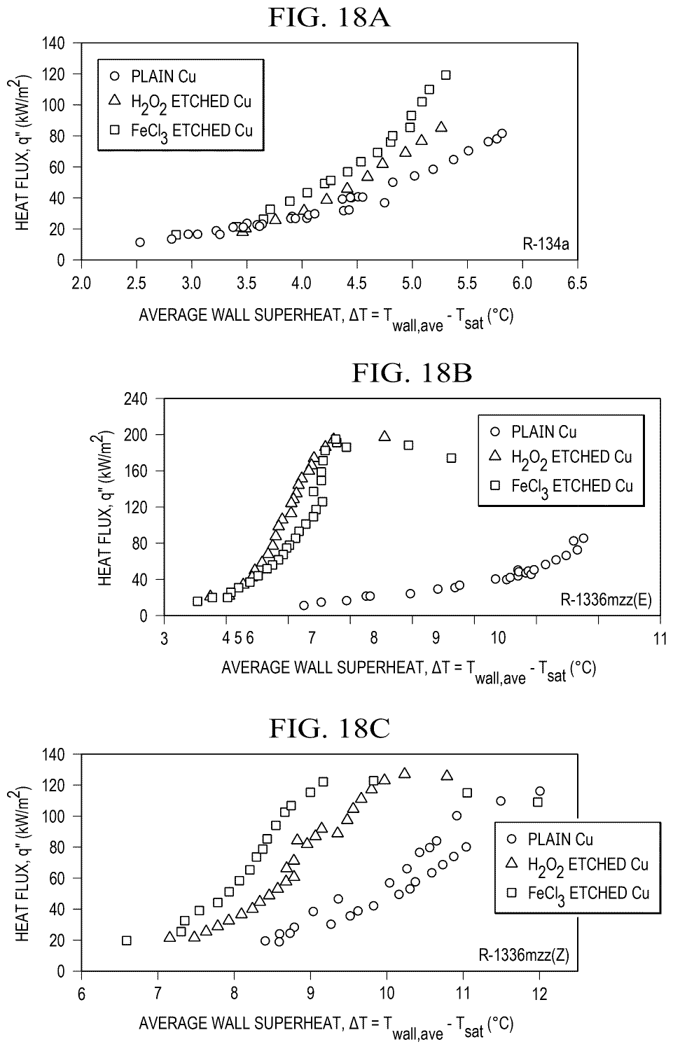

With some modern electronic components reaching heat fluxes as high as 400 W/cm², the CHF of refrigerants has become a crucial metric in the design of cooling systems. The heat flux as a function of average wall superheat (q″vs. ΔT) for low-GWP refrigerants R-1336mzz(E) and R-1336mzz(Z) in both nucleate and transition boiling regimes are plotted in FIGS. 18A-18C. Boiling curves for both chemically etched Cu surfaces and plain Cu surfaces in R-134a are also depicted for reference. The average wall superheat ΔT is defined as the difference between the average wall temperature T_{wall,avg} and the saturation temperature Tₛₐₜ, and can be calculated as:

$$Δ T = {T}_{wall , avg} - {T}_{s a t} = \frac{{q}^{″}}{{h}_{o}} . \qquad ( 9 )$$

For R-134a, at the same level of superheat, the heat flux produced by the FeCl₃ Etched Cu tube is greater than that produced by the H₂O₂ etched tube, which in turn is greater than that of the plain Cu tube. It is evident that the derivative of the heat flux with respect to average wall superheat monotonically increases for all three curves, indicating that the entire boiling curve is still in the early stages of nucleate boiling, and the current heat flux q″ is still far from reaching CHF. For R-1336mzz(E), the complete boiling curve for etched Cu is obtained. For both the FeCl₃ and the H₂O₂ Etched Cu tubes, the heat flux first increases and then decreases with increasing wall superheat. In the nucleate boiling regime, the slope of the curve increases initially and then decreases. The performance of the two types of etched Cu is similar, with the heat flux reaching its maximum value at an average wall superheat of 6.5° C., amounting to a CHF of 185 kW/m². When ΔT>6.5° C., the continuous increase in the flow rate of vapor leaving the surface pushes the mechanisms facilitating liquid flow toward the surface to their maximum limits. At this point, vapor may accumulate at certain locations near the surface, and the evaporation of liquid between the surface and these adjacent vapor regions may cause parts of the surface to dry out. Since the dry parts of the surface covered by a vapor film has a much lower local heat flux compared to the wet parts of the surface undergoing nucleate boiling, the boiling HTC may start to decrease. For R-1336mzz(E), the reduction in wall superheat at the same heat flux for modified surfaces compared to plain Cu tubes is significant, with the highest reductions showing a halving of the superheat. Such improvements are beneficial in enhancing heat transfer efficiency and reducing energy consumption, whether in shell and tube heat exchangers for chillers or for electronics cooling applications.

Compared to plain Cu tubes, modified surfaces also facilitate enhanced boiling of R-1336mzz(Z) at the same ΔT. Among them, the enhancement effect of the FeCl₃ Etched Cu tube is greater than that of the H₂O₂ Etched Cu tube. Interestingly, due to the limitations of the cooling power of the chiller, it was not possible to measure the CHF of the plain tubes with both low-GWP refrigerants, R-1336mzz(E) and R-1336mzz(Z). This implies that the CHF of modified surfaces is lower compared to that of plain Cu tubes. Generally, for water pool boiling, microstructured surfaces enhance the CHF by improving the wicking properties and ensuring the wettability of the surface remains exceptional. However, many studies have questioned whether wicking structures can enhance the CHF of refrigerants. Refrigerants are low surface tension fluids, hence the contact angle with plain tubes already approaches 0°,making improvement of wicking a difficult task. Many studies have observed the same phenomenon of reduced CHF as observed here for both pool boiling and flow boiling. A plausible explanation is that enhanced surfaces at high heat fluxes switch to a Cassie-Baxter wetting state, causing the microstructures to trap bubbles and thus lower the CHF.

In addition to the aforementioned impacts of POE oil and tube bundle configurations on pool boiling behavior, further research prospects include evaluating the performance enhancements of modified surfaces with other widely used refrigerants, such as CO₂, propane, or ammonia. Although some of these refrigerants pose challenges—high pressures, pronounced flammability, or toxicity, but they provide unrivaled performance benefits at the system level. Moreover, certain refrigerant blends merit consideration, particularly specific zeotropic blends like R-454(a), R-454(b), and R-454(c), which consist of varying concentrations of R-32 and R-1234yf. These mixtures have become established commercial replacements for R-134a in chillers. However, their zeotropic characteristics lead to component composition shifts with changing operating conditions, creating a compositional discrepancy between the tube wall and the bulk fluid during pool boiling. This discrepancy further fluctuates with variations in heat flux and HTC. Etched surfaces generally exhibit excellent durability in pure refrigerants. However, in industrial applications, they are susceptible to the effects of lubricant oil adsorption on the surface. Numerous studies have already investigated the boiling performance of modified surfaces in refrigerant-lubricant mixtures. Generally, pool boiling performance degradation remains within 10% as lubricant concentration varies. Nevertheless, the long-term effects of lubricant accumulation on these surfaces remain to be thoroughly investigated. Consequently, accurately modeling the enhancement effect of modified surfaces on pool boiling performance under these complex conditions presents a substantial challenge. Finally, burst pressure presents another intriguing consideration. Commercial finned tubes, with their additional irregular protrusions and angular structures, are more prone to stress concentration under high pressures, potentially leading to material failure. In this regard, etched copper tubes may offer a more robust solution; however, further investigation is needed to clarify the specific parametric differences.

The subject matter of this disclosure includes the following aspects:

A first aspect relates to a pool boiling system comprising: a pool comprising a liquid refrigerant; and a component partially or fully submerged in the pool, the component having a microstructured surface including cavities having a linear size of at least 5 μm, the microstructured surface being in contact with the liquid refrigerant, wherein the system exhibits a pool boiling heat transfer coefficient (HTC) of at least about 8 kW/m²K for a heat flux in a range from 15-85 kW/m².

A second aspect relates to the pool boiling system of the first aspect, wherein the linear size of the cavities is at least 10 μm, or at least 20 μm, and/or up to 100 μm.

A third aspect relates to the pool boiling system of the first or second aspect, wherein the cavities of the microstructured surface having the linear size of at least 5 μm, at least 10 μm, or at least 20 μm, and/or up to 100 μm, account for at least 70%, at least 80%, or at least 90%, and/or up to 100% of all cavities of the microstructured surface.

A fourth aspect relates to the pool boiling system of any preceding aspect, wherein the HTC is at least 12 kW/m²K, at least 20 kW/m²K, or at least 30 kW/m²K, and/or as high as 50 kW/m²K at the heat flux in the range from 15-85 kW/m².

A fifth aspect relates to the pool boiling system of any preceding aspect, wherein the liquid refrigerant has a global warming potential (GWP) of less than 1,500, and/or less than 20.

A sixth aspect relates to the pool boiling system of any preceding aspect, wherein the liquid refrigerant comprises R134a, R1336mzz(E), R1336mzz(Z), a zeotropic blend, or an azeotropic blend.

A seventh aspect relates to the pool boiling system of any preceding aspect, wherein the liquid refrigerant comprises a dielectric fluid such as a fluorinated ketone.

An eighth aspect relates to the pool boiling system of any preceding claim, wherein the component comprises aluminum or copper.

A ninth aspect relates to the pool boiling system of any preceding aspect, wherein the component comprises a tube or a bundle of tubes, and the microstructured surface is part or all of an external surface of the tube or the bundle of tubes.

A tenth aspect relates to the pool boiling system of the preceding aspect, wherein the tube or the bundle of tubes is configured for flow of water or another coolant liquid therethrough.

An eleventh aspect relates to the pool boiling system of any preceding aspect, wherein the component comprises an electronic device or a heat spreader in contact with the electronic device, and the microstructured surface is part or all of an external surface of the heat spreader or the electronic device.

A twelfth aspect relates to the pool boiling system of any preceding aspect exhibiting a refrigerant boiling HTC enhancement ratio of at least 1.5.

A thirteenth aspect relates to the pool boiling system of any preceding aspect exhibiting a normalized structure size Rₙ greater than 4.

A fourteenth aspect relates to a method of transferring heat via pool boiling, the method comprising: partially or fully submerging a component in a pool comprising a liquid refrigerant, the component having a microstructured surface including cavities having a linear size of at least 5 μm, the microstructured surface being in contact with the liquid refrigerant; and transferring heat generated by or originating within the component via boiling of the liquid refrigerant at the microstructured surface, wherein a pool boiling heat transfer coefficient (HTC) of at least about 8 kW/m²K for a heat flux in a range from 15-85 kW/m² is achieved.

A fifteenth aspect relates to the method of the preceding aspect, wherein the linear size of the cavities is at least 10 μm, or at least 20 μm, and/or up to 100 μm, or up to 200 μm.

A sixteenth aspect relates to the method of the fourteenth or fifteenth aspect, wherein the cavities of the microstructured surface having the linear size account for at least 70%, at least 80%, at least 90%, and/or up to 100% of all cavities of the microstructured surface.

A seventeenth aspect relates to the method of any preceding aspect, wherein the HTC is at least 12 kW/m²K, at least 20 kW/m²K, or at least 30 kW/m²K, and/or as high as 50 kW/m²K at the heat flux in the range from 15-85 kW/m².

An eighteenth aspect relates to the method of any preceding aspect, wherein the liquid refrigerant has a global warming potential (GWP) of less than 1,500, and/or less than 20.

A nineteenth aspect relates to the method of any preceding claim, wherein the liquid refrigerant comprises R134a, R1336mzz(E), R1336mzz(Z), a zeotropic blend, or an azeotropic blend.

A twentieth aspect relates to the method of any preceding aspect, wherein the liquid refrigerant comprises a dielectric fluid such as a fluorinated ketone.

A twenty-first aspect relates to the method of any preceding aspect, wherein the component comprises aluminum or copper.

A twenty-second aspect relates to the method of any preceding aspect, wherein the component comprises a tube or a bundle of tubes, and the microstructured surface is part or all of an external surface of the tube or the bundle of tubes.

A twenty-third aspect relates to the method of any preceding aspect, wherein the tube or the bundle of tubes is configured for flow of water or another coolant liquid therethrough.

A twenty-fourth aspect relates to the method of any preceding aspect, wherein the component comprises an electronic device or a heat spreader in contact with the electronic device, and the microstructured surface is part or all of an external surface of the heat spreader or the electronic device.

A twenty-fifth aspect relates to the method of any preceding aspect, wherein a refrigerant boiling HTC enhancement ratio of at least 1.5 is obtained.

A twenty-sixth aspect relates to the method of any preceding aspect, wherein a normalized structure size Rₙ is greater than 4.

A twenty-seventh aspect relates to a method for producing an etched copper component for a pool boiling system, the method comprising: exposing a component comprising copper to an etchant solution comprising: an oxidant selected from the group consisting of ferric chloride and hydrogen peroxide; and hydrochloric acid, wherein the oxidant and the hydrochloric acid have a volume ratio in a range from 1:6 to 1:8 in the etchant solution.

A twenty-eighth aspect relates to the method of the preceding aspect, wherein the exposure to the etchant solution takes place for a time duration from 2 hours to 30 hours.

A twenty-ninth aspect relates to the method of the twenty-seventh or twenty-eighth aspect, wherein the oxidant is ferric chloride, and wherein the time duration is from 2 hours to 8 hours.

A thirtieth aspect relates to the method of the twenty-seventh or twenty-eighth aspect, wherein the oxidant is hydrogen peroxide, and wherein the time duration is from 20 hours to 30 hours.

A thirty-first aspect relates to the method of any of the twenty-seventh through the thirtieth aspects, wherein the volume ratio is in the range from 1.7 to 1.8.

To clarify the use of and to hereby provide notice to the public, the phrases “at least one of <A>, <B>, . . . and <N>” or “at least one of <A>, <B>, . . . or <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

While various embodiments have been described, it will be apparent to those of ordinary skill in the art that many more embodiments and implementations are possible. Accordingly, the embodiments described herein are examples, not the only possible embodiments and implementations.

In addition to the features mentioned in each of the independent aspects enumerated above, some examples may show, alone or in combination, the optional features mentioned in the dependent aspects and/or as disclosed in the description above and shown in the figures.

1. A pool boiling system comprising:
a pool comprising a liquid refrigerant; and
a component partially or fully submerged in the pool, the component having a microstructured surface including cavities having a linear size of at least 5 μm, the microstructured surface being in contact with the liquid refrigerant,
wherein the system exhibits a pool boiling heat transfer coefficient (HTC) of at least about 8 kW/m²K for a heat flux in a range from 15-85 kW/m².

2. The pool boiling system of claim 1, wherein the linear size of the cavities is in a range from 10 μm to 200 μm.

3. The pool boiling system of claim 1, wherein the cavities having the linear size account for at least 70% of all cavities of the microstructured surface.

4. The pool boiling system of claim 1, wherein the HTC is in a range from 12 kW/m²K to 50 kW/m²K at the heat flux in the range from 15-85 kW/m².

5. The pool boiling system of claim 1, wherein the liquid refrigerant has a global warming potential (GWP) of less than 1,500.

6. The pool boiling system of claim 1, wherein the component comprises aluminum or copper.

7. The pool boiling system of claim 1, wherein the component comprises a tube or a bundle of tubes, and the microstructured surface is part or all of an external surface of the tube or the bundle of tubes.

8. The pool boiling system of claim 1, wherein the component comprises an electronic device or a heat spreader in contact with the electronic device, and the microstructured surface is part or all of an external surface of the heat spreader or the electronic device.

9. The pool boiling system of claim 1 exhibiting a refrigerant boiling HTC enhancement ratio of at least 1.5.

10. The pool boiling system of claim 1 exhibiting a normalized structure size Rₙ greater than 4.

11. A method of transferring heat via pool boiling, the method comprising:
partially or fully submerging a component in a pool comprising a liquid refrigerant, the component having a microstructured surface including cavities having a linear size of at least 5 μm, the microstructured surface being in contact with the liquid refrigerant; and
transferring heat generated by or originating within the component via boiling of the liquid refrigerant at the microstructured surface,
wherein a pool boiling heat transfer coefficient (HTC) of at least about 8 kW/m²K for a heat flux in a range from 15-85 kW/m² is achieved.

12. The method of claim 11, wherein the linear size of the cavities is in a range from 10 μm to 100 μm.

13. The method of claim 11, wherein the cavities having the linear size account for at least 70% of all cavities of the microstructured surface.

14. The method of claim 11, wherein the HTC is in a range from 12 kW/m²K to 50 kW/m²K at the heat flux in the range from 15-85 kW/m².

15. The method of claim 11, wherein the liquid refrigerant comprises R134a, R1336mzz(E), R1336mzz(Z), a zeotropic blend, an azeotropic blend, or a dielectric fluid.

16. The method of claim 11, wherein the component comprises aluminum or copper.

17. The method of claim 11, wherein the component comprises a tube or a bundle of tubes, and the microstructured surface is part or all of an external surface of the tube or the bundle of tubes.

18. The method of claim 11, wherein the component comprises an electronic device or a heat spreader in contact with the electronic device, and the microstructured surface is part or all of an external surface of the heat spreader or the electronic device.

19. A method for producing an etched copper component for a pool boiling system, the method comprising:
exposing a component comprising copper to an etchant solution including: an oxidant selected from the group consisting of ferric chloride and hydrogen peroxide; and hydrochloric acid,
wherein the oxidant and the hydrochloric acid have a volume ratio in a range from 1:6 to 1:8 in the etchant solution.

20. The method of claim 19, wherein the exposure to the etchant solution takes place for a time duration from 2 hours to 30 hours.
